(19) United States
(12) Patent Application Publication
(10) Pub. No.: US 2026/0003267 A1
(43) Pub. Date: Jan. 1, 2026

(54) RADIATION-SENSITIVE COMPOSITION, METHOD FOR FORMING PATTERN, AND ONIUM SALT

(71) Applicant: JSR CORPORATION, Tokyo (JP)

(72) Inventors: Ryuichi NEMOTO, Tokyo (JP); Yuichi HIKAMI, Tokyo (JP); Michihiro MITA, Tokyo (JP); Masayuki MIYAKE, Tokyo (JP); Hajime INAMI, Tokyo (JP)

(73) Assignee: JSR CORPORATION, Tokyo (JP)

(21) Appl. No.: 19/317,301

(22) Filed: Sep. 3, 2025

Related U.S. Application Data
(63) Continuation-in-part of application No. PCT/JP2024/010654, filed on Mar. 19, 2024.

(30) Foreign Application Priority Data
Apr. 7, 2023 (JP) 2023-062675

(51) Int. Cl. G03F 7/004; C08F 20/18; G03F 7/00; G03F 7/038; G03F 7/039

(52) U.S. Cl. CPC G03F 7/0045; C08F 20/18; G03F 7/0046; G03F 7/0382; G03F 7/0388; G03F 7/0397; G03F 7/70025; G03F 7/70033; G03F 7/70341

(57) ABSTRACT

A radiation-sensitive composition includes: an onium salt represented by formula (1); a polymer including a structural unit (I) which includes an acid-dissociable group; and a solvent. Q¹ and Q² are each independently a carbon atom or a nitrogen atom, provided that at least one selected from the group consisting of Q¹ and Q² is a carbon atom; W is a monocyclic or polycyclic non-aromatic ring structure of 3 to 40 ring members together with Q¹ and Q², and the formula between Q¹ and Q² represents a single bond or a double bond, R¹ is a monovalent organic group having 1 to 20 carbon atoms, a nitro group, a hydroxy group, an amino group, a thiol group, a cyano group, a carboxy group, or halogen atom; m₁ is an integer of 0 to 4; and Z⁺ is a monovalent onium cation.

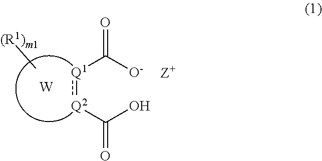

### CROSS-REFERENCE TO RELATED APPLICATIONS

The present application is a continuation-in-part application of International Patent Application No. PCT/JP2024/010654 filed Mar. 19, 2024, which claims priority to Japanese Patent Application No. 2023-062675 filed Apr. 7, 2023. The contents of these applications are incorporated herein by reference in their entirety.

### BACKGROUND OF THE DISCLOSURE

### Technical Field

The present disclosure relates to a radiation-sensitive composition, a method for forming a pattern, and an onium salt.

### Background Art

A photolithography technology using a resist composition has been used for the fine circuit formation in a semiconductor device. As the representative procedure, for example, a resist pattern is formed on a substrate by generating an acid by irradiating the coating of the resist composition with a radioactive ray through a mask pattern, and then reacting in the presence of the acid as a catalyst to generate the difference of solubility of a polymer into an alkaline or organic developer between an exposed part and a non-exposed part.

In the photolithography technique, the micronization of the pattern is promoted by using a short-wavelength radioactive ray such as an ArF excimer laser or by using an immersion exposure method (liquid immersion lithography) in which exposure is performed in a state in which a space between a lens of an exposure apparatus and a resist film is filled with a liquid medium.

While efforts for further technological development are in progress, a technique has been proposed in which a quencher (acid diffusion controlling agent) is blended in a resist composition, and an acid diffused to a non-exposed part is captured by a salt exchange reaction to improve lithographic performance with ArF exposure (JP-B-5556765). In addition, as a next-generation technology, lithography using a shorter-wavelength radioactive ray such as an electron beam, an X-ray, and extreme ultraviolet (EUV) is also being studied.

### SUMMARY

According to an aspect of the present disclosure, a radiation-sensitive composition includes: an onium salt represented by formula (1) (hereinafter, also referred to as an “onium salt (1)”); a polymer including a structural unit (I) which includes an acid-dissociable group; and a solvent.

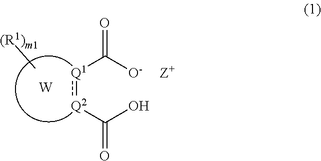

Q¹ and Q² are each independently a carbon atom or a nitrogen atom, provided that at least one selected from the group consisting of Q¹ and Q² is a carbon atom; W is a monocyclic or polycyclic non-aromatic ring structure of 3 to 40 ring members constituted together with Q¹ and Q² in the formula, and the following formula between Q¹ and Q² in formula (1) represents a single bond or a double bond,

[symbol]

R¹ is a monovalent organic group having 1 to 20 carbon atoms, a nitro group, a hydroxy group, an amino group, a thiol group, a cyano group, a carboxy group, or halogen atom, when there are a plurality of R¹'s, the plurality of R¹'s are the same or different from each other; m₁ is an integer of 0 to 4; and Z⁺ is a monovalent onium cation.

According to another aspect of the present disclosure, a method for forming a pattern, includes: directly or indirectly applying the above-described radiation-sensitive composition to a substrate to form a resist film; exposing the resist film to light; and developing the resist film exposed to light with a developer.

According to a further aspect of the present disclosure, an onium salt is represented by formula (1).

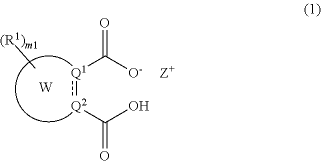

Q¹ and Q² are each independently a carbon atom or a nitrogen atom, provided that at least one selected from the group consisting of Q¹ and Q² is a carbon atom; W is a monocyclic or polycyclic non-aromatic ring structure of 3 to 40 ring members constituted together with Q¹ and Q² in the formula, and the following formula between Q¹ and Q² in formula (1) represents a single bond or a double bond,

[symbol]

R¹ is a monovalent organic group having 1 to 20 carbon atoms, a nitro group, a hydroxy group, an amino group, a thiol group, a cyano group, a carboxy group, or halogen atom, when there are a plurality of R¹'s, the plurality of R¹'s are the same or different from each other; m₁ is an integer of 0 to 4; and Z⁺ is a monovalent onium cation.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Among such efforts for the next-generation technology, various resist performances equal to or higher than ever before are required in terms of sensitivity, line width roughness (LWR) performance indicating variation in line width of a resist pattern, DOF (Depth Of Focus) performance, pattern rectangularity indicating the rectangularity of the sectional shape of a resist pattern, critical dimension uniformity (CDU) performance, which is an index of uniformity of line width and hole diameter, pattern circularity indicating the circularity of a hole shape, EL (Exposure Latitude) performance, pattern collapse resistance, and the like.

In the present disclosure, since the radiation-sensitive composition contains an onium salt (1) as a quencher (acid diffusion controlling agent), various excellent resist performances such as sensitivity, LWR performance, DOF performance, pattern rectangularity, CDU performance, pattern circularity, EL performance, and pattern collapse resistance can be exhibited when a resist pattern is formed.

The reason for this is not bound by any theory, but can be expected as follows. Due to the structural proximity between the carboxy group and the anion thereof on two adjacent carbon atoms of the onium salt (1), the hydrogen bonding ability therebetween decreases, and as a result, the basicity of the onium salt (1) is enhanced as compared with the case of having the carboxy group and the anion thereof on the same carbon, and the acid capturing property in the non-exposed part can be improved. The dissolution contrast between the exposed part and the non-exposed part can be increased by introducing a structure having a relatively high polarity such as a carboxy group and an anion thereof. By adopting a non-aromatic ring structure as the main skeleton, it is possible to improve dispersibility and compatibility in a resist film while securing transparency (non-absorbability) to exposure light as compared with the case of adopting an aromatic ring structure or a chain structure. It is presumed that various resist performances can be exerted due to synergistic action of these factors. It is to be noted that an organic group is a group containing at least one carbon atom. However, the functional group containing a carbon atom or the characteristic group (cyano group, carboxy group, carbonyl group, or the like) itself is not included in the organic group.

In the method for forming a pattern of the present disclosure, a high-quality resist pattern can be efficiently formed because of the use of the radiation-sensitive composition capable of forming a resist film or a pattern excellent in sensitivity, LWR performance, DOF performance, pattern rectangularity, CDU performance, pattern circularity, EL performance, and pattern collapse resistance.

In the present disclosure, since the onium salt (1) can exhibit good basicity, polarity, and transparency in a resist film, when it is blended in a radiation-sensitive composition, excellent sensitivity, LWR performance, DOF performance, pattern rectangularity, CDU performance, pattern circularity, EL performance, and pattern collapse resistance can be exhibited when a resist pattern is formed.

Hereinafter, embodiments of the present disclosure will be described in detail, but the present disclosure is not limited to these embodiments. Combinations of suitable modes in the embodiments are also preferred.

### <Radiation-Sensitive Composition>

A radiation-sensitive composition (hereinafter, also simply referred to as “composition”) according to the present embodiment contains an onium salt (1), a polymer, and a solvent. The radiation-sensitive composition further contains a radiation-sensitive acid generator, as necessary. The composition may contain other optional components as long as the effects of the present disclosure are not impaired. When the radiation-sensitive composition contains a predetermined onium salt (1), excellent sensitivity, LWR performance, DOF performance, pattern rectangularity, CDU performance, pattern circularity, EL performance, and pattern collapse resistance can be exhibited when a resist pattern is formed.

### (Onium Salt (1))

The onium salt (1) can function as a quencher (also referred to as a “photodegradable base” or “acid diffusion controlling agent”) that captures acid before exposure or acid in a non-exposed part. The onium salt (1) is represented by the above formula (1).

In the above formula (1), both Q¹ and Q² are preferably a carbon atom.

In the above formula (1), the monocyclic or polycyclic non-aromatic ring structure of 3 to 40 ring members constituted together with Q¹ and Q² in the formula, which is represented by W, may be either a monocyclic or polycyclic structure as long as it is a non-aromatic ring structure (having no aromatic property) of 3 to 40 ring members, and may be either saturated or unsaturated. The polycyclic structure may be a fused ring structure in which two adjacent rings share one side (bond between two adjacent atoms), may be a bridged ring structure in which two carbon atoms that are not adjacent to each other among carbon atoms constituting the ring are bonded by a linking group containing one or more atoms, may be a ring structure in which two adjacent rings are bonded by a single bond, or may be a spiro ring structure in which two adjacent rings share one carbon atom. The combination of two adjacent rings may be any of a combination of a monocyclic ring and a monocyclic ring, a combination of a monocyclic ring and a polycyclic ring, and a combination of a polycyclic ring and a polycyclic ring. The ring-constituting atom may contain a heteroatom in addition to a carbon atom. Examples of the heteroatom include an oxygen atom, a sulfur atom, and a nitrogen atom. The number of ring members is the sum of ring-constituting atoms including Q¹ and Q² in W.

The non-aromatic ring structure is preferably a monocyclic or polycyclic aliphatic hydrocarbon structure having 3 to 20 carbon atoms, a monocyclic or polycyclic aliphatic heterocyclic structure having 3 to 20 carbon atoms, or a combination thereof.

Examples of the monocyclic or polycyclic aliphatic hydrocarbon structure having 3 to 20 carbon atoms include a monocyclic or polycyclic cycloalkane structure and a monocyclic or polycyclic cycloalkene structure. The monocyclic cycloalkane structure is preferably a cyclopropane ring, a cyclobutane ring, a cyclopentane ring, a cyclohexane ring, a cycloheptane ring, or a cyclooctane ring. The polycyclic cycloalkane structure is preferably bridged ring structure such as a norbornane ring, an adamantane ring, a tricyclodecane ring, or a tetracyclododecane ring. Examples of the monocyclic cycloalkene structure include monocyclic cycloalkenyl groups such as a cyclopropene ring, a cyclobutene ring, a cyclopentene ring, and a cyclohexene ring. Examples of the polycyclic cycloalkene structure include a norbornene ring, a tricyclodecene ring, and a tetracyclododecene ring.

Examples of the monocyclic or polycyclic aliphatic heterocyclic structure having 3 to 20 carbon atoms include a structure in which some carbon atoms constituting a ring of the monocyclic or polycyclic aliphatic hydrocarbon structure having 3 to 20 carbon atoms are substituted with —CO—, —CS—, —O—, —S—, —SO₂—, —NR′—, or a divalent heteroatom-containing group obtained by combining two or more thereof. R′ is a hydrogen atom or a monovalent hydrocarbon group having 1 to 10 carbon atoms.

Examples of the aliphatic heterocyclic structure include:
oxygen atom-containing aliphatic heterocyclic structures such as oxirane, tetrahydrofuran, tetrahydropyran, dioxolane, and dioxane (for example, cyclic acetal);
nitrogen atom-containing aliphatic heterocyclic structures such as aziridine, pyrrolidine, piperidine, and piperazine;
sulfur atom-containing aliphatic heterocyclic structures such as thietane, thiolane, and thiane; and
aliphatic heterocyclic structures containing two or more heteroatoms such as morpholine, 1,2-oxathiolane, and 1,3-oxathiolane; and
a lactone structure, a cyclic carbonate structure, a sultone structure, and cyclic acetal structure.

The non-aromatic ring structure is preferably a cyclopentane ring, a cyclohexane ring, a cycloheptane ring, a cyclooctane ring, a norbornane ring, a tricyclodecane ring, a tetracyclododecane ring, an adamantane ring, a ring structure in which some carbon atoms constituting these ring structures are substituted with —O—, —CO—, or a combination thereof (a cyclic ether structure, a cyclic ketone structure, a lactone structure, or a cyclic acetal structure), or a combination thereof.

The monovalent organic group having 1 to 20 carbon atoms represented by R¹ is preferably, for example, a substituted or unsubstituted monovalent chain hydrocarbon group having 1 to 20 carbon atoms, a substituted or unsubstituted monovalent alicyclic hydrocarbon group having 3 to 20 carbon atoms, a substituted or unsubstituted monovalent aromatic hydrocarbon group having 6 to 20 carbon atoms, or a combination thereof. A group in which some or all of hydrogen atoms contained in the chain, alicyclic, and aromatic hydrocarbon groups are substituted with a substituent, a group containing the divalent heteroatom-containing group between carbon and carbon of these groups or at the terminal of the group, and the like are also included.

Examples of the substituent that substitutes part or all of the hydrogen atoms of the organic group include halogen atoms such as a fluorine atom, a chlorine atom, a bromine atom, and an iodine atom; a hydroxy group; a carboxy group; a cyano group; a nitro group; an alkyl group, an alkoxy group, an alkoxycarbonyl group, an alkoxycarbonyloxy group, an acyl group, an acyloxy group, or a group in which a hydrogen atom of these groups has been substituted with a halogen atom; and an oxo group (═O).

Examples of the monovalent chain hydrocarbon group having 1 to 20 carbon atoms include a linear or branched saturated hydrocarbon group having 1 to 20 carbon atoms, or a linear or branched unsaturated hydrocarbon group having 1 to 20 carbon atoms.

As the monovalent alicyclic hydrocarbon group having 3 to 20 carbon atoms, a group obtained by removing one hydrogen atom from the monocyclic or polycyclic aliphatic hydrocarbon structure having 3 to 20 carbon atoms in W can be suitably employed.

Examples of the monovalent aromatic hydrocarbon group having 6 to 20 carbon atoms include aryl groups such as a phenyl group, a tolyl group, a xylyl group, a naphthyl group, and an anthryl group; and aralkyl groups such as a benzyl group, a phenethyl group, and a naphthylmethyl group.

m₁ is preferably an integer of 0 to 3, and more preferably an integer of 0 to 2.

An anion moiety of the onium salt (1) represented by the formula (1) is not particularly limited, and examples thereof include structures represented by formulas (1-1-1) to (1-1-33) below.

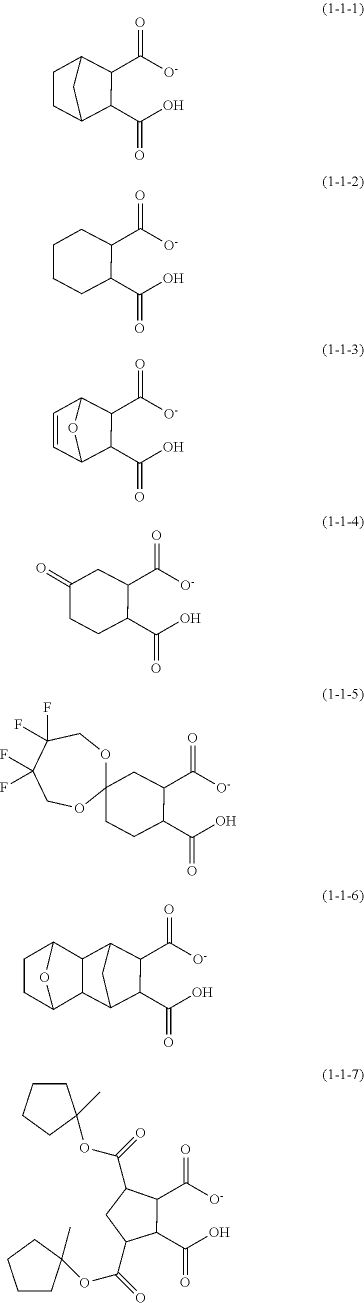

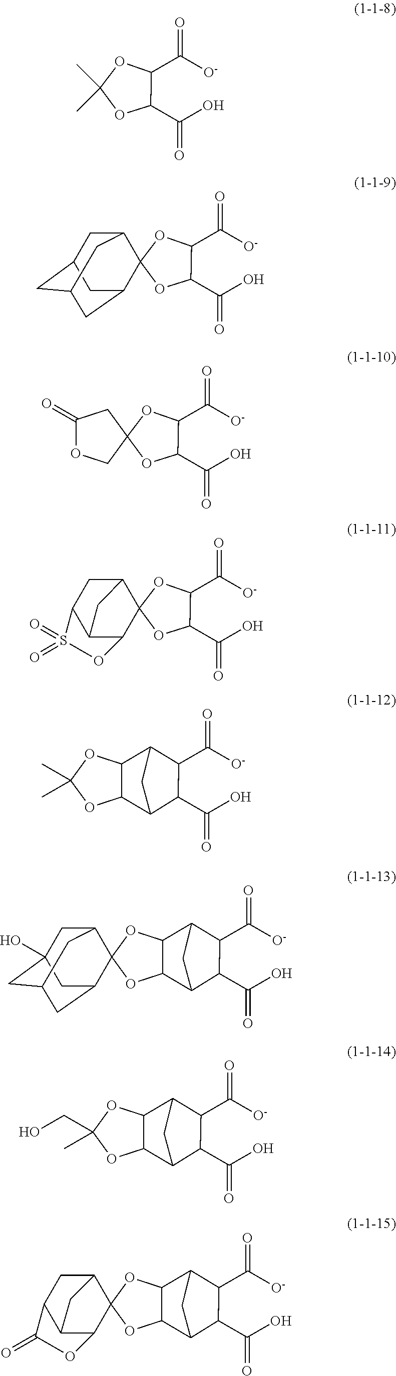

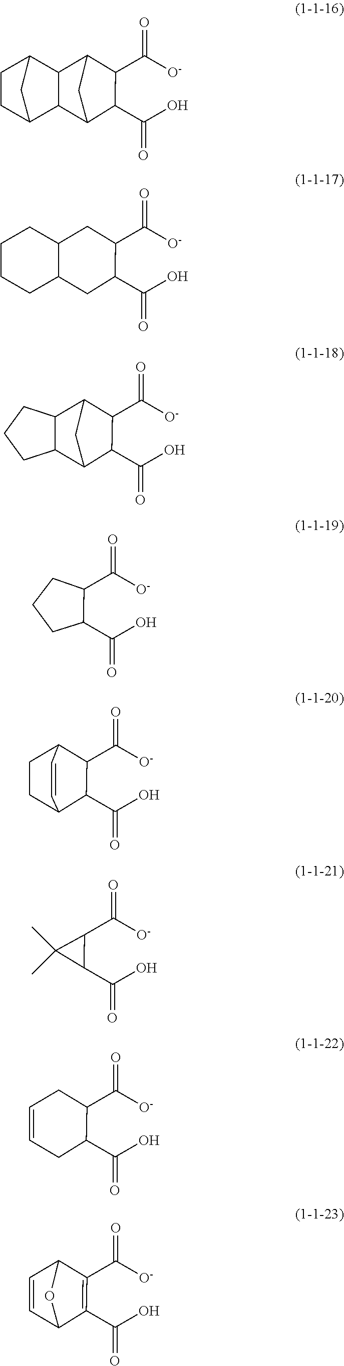

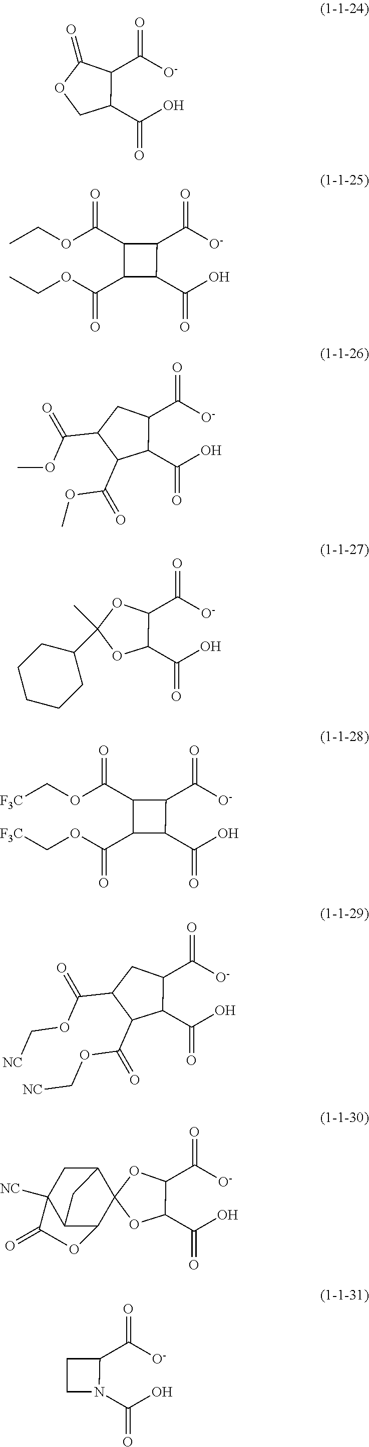

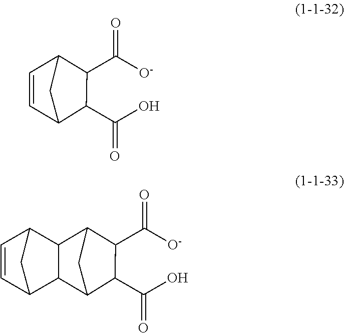 [SMILES: O=C([O-])C1C2C=CC(C2)C1C(=O)O ; O=C([O-])C1C2CC(C1C(=O)O)C1C3C=CC(C3)C21]

Examples of the monovalent onium cation represented by Z⁺ in the formula (1) include an onium cation containing an element such as S, I, O, N, P, Cl, Br, F, As, Se, Sn, Sb, Te, and Bi. The onium cation is preferably a radiolytic onium cation. Examples of the radiolytic onium cation include a sulfonium cation, a tetrahydrothiophenium cation, an iodonium cation, a phosphonium cation, a diazonium cation, and a pyridinium cation. Among them, a sulfonium cation or an iodonium cation is preferred. Z⁺ preferably contains at least one aromatic ring, and more preferably is a monovalent sulfonium cation containing at least one aromatic ring or a monovalent iodonium cation containing at least one aromatic ring.

The sulfonium cation or the iodonium cation is preferably represented by any of formulas (X-1) to (X-6).

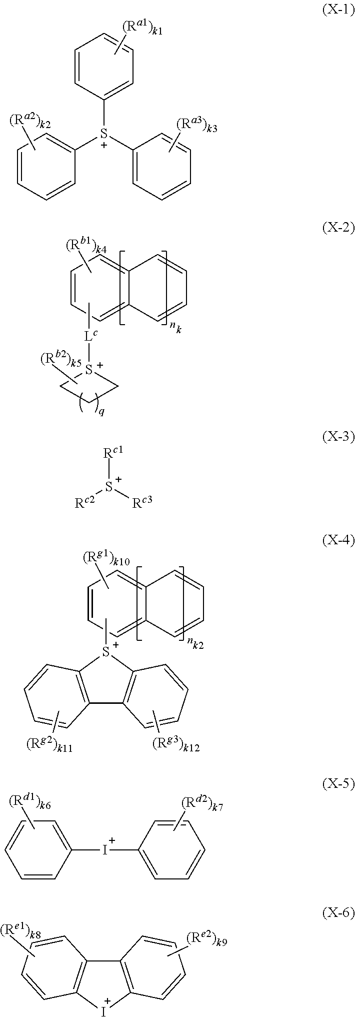

In the above formula (X-1), R^{a1}, R^{a2} and R^{a3} are each independently a substituted or unsubstituted, straight or branched chain alkyl group, alkoxy group or alkoxycarbonyloxy group having a carbon number of 1 to 12; a substituted or unsubstituted, monocyclic or polycyclic cycloalkyl group having a carbon number of 3 to 12; a substituted or unsubstituted aromatic hydrocarbon group having a carbon number of 6 to 12; a hydroxy group, a halogen atom, —OSO₂—R^{P}, —SO₂—R^{Q} or —S—R^{T}; or a ring structure obtained by combining two or more of these groups. The ring structure may contain heteroatoms such as O and S between the carbon-carbon bonds forming the skeleton. R^{P}, R^{Q} and R^{T} are each independently a substituted or unsubstituted, straight or branched chain alkyl group having a carbon number of 1 to 12; a substituted or unsubstituted alicyclic hydrocarbon group having a carbon number of 5 to 25; and a substituted or unsubstituted aromatic hydrocarbon group having a carbon number of 6 to 12. k1, k2 and k3 are each independently an integer of 0 to 5. When there are a plurality of R^{a1} to R^{a3} and a plurality of R^{P}, R^{Q} and R^{T}, a plurality of R^{a1} to R^{a3} and a plurality of R^{P}, R^{Q} and R^{T} may be each identical or different.

In the above formula (X-2), R^{b1} is a substituted or unsubstituted, straight chain or branched alkyl group or alkoxy group having a carbon number of 1 to 20; a substituted or unsubstituted acyl group having a carbon number of 2 to 8; or a substituted or unsubstituted aromatic hydrocarbon group having a carbon number of 6 to 8; or a halogen atom; or a hydroxy group. nₖ is 0 or 1. When nₖ is 0, k4 is an integer of 0 to 4. When nₖ is 1, k4 is an integer of 0 to 7. When there are a plurality of R^{b1}, a plurality of R^{b1} may be each identical or different. A plurality of R^{b1} may represent a ring structure obtained by combining them. R^{b2} is a substituted or unsubstituted, straight chain or branched alkyl group having a carbon number of 1 to 7; or a substituted or unsubstituted aromatic hydrocarbon group having a carbon number of 6 or 7. L^{C} is a single bond or divalent linking group. k5 is an integer of 0 to 4. When there are a plurality of R^{b2}, a plurality of R^{b2} may be each identical or different. A plurality of R^{b2} may represent a ring structure obtained by combining them. q is an integer of 0 to 3. In the formula, the ring structure containing S⁺ may contain a heteroatom such as O or S between the carbon-carbon bonds forming the skeleton.

In the above formula (X-3), R^{c1}, R^{c2} and R^{c3} are each independently a substituted or unsubstituted, straight or branched chain alkyl group having a carbon number of 1 to 12.

In the above formula (X-4), R^{g1} is a substituted or unsubstituted linear or branched alkyl or alkoxy group having 1 to 20 carbon atoms, a substituted or unsubstituted acyl group having 2 to 8 carbon atoms, a substituted or unsubstituted aromatic hydrocarbon group having 6 to 8 carbon atoms, a halogen atom, or a hydroxy group. nₖ is 0 or 1. When nₖ2 is 0, k10 is an integer of 0 to 4, and when nₖ2 is 1, k10 is an integer of 0 to 7. When there are two or more Rols, the two or more Rols are the same or different from each other, and may represent a cyclic structure formed by combining them together. R^{g2} and R^{g3} are each independently a substituted or unsubstituted linear or branched alkyl, alkoxy, or alkoxycarbonyloxy group having 1 to 12 carbon atoms, a substituted or unsubstituted monocyclic or polycyclic cycloalkyl group having 3 to 12 carbon atoms, a substituted or unsubstituted aromatic hydrocarbon group having 6 to 12 carbon atoms, a hydroxyl group, a halogen atom, or a ring structure formed by combining two or more of these groups together. K11 and k12 are each independently an integer of 0 to 4. When there are two or more R^{g2}s and two or more R^{g3}s, the two or more R^{g2}s may be the same or different from each other, and the two or more R^{g3}s may be the same or different from each other.

In the above formula (X-5), R^{d1} and R^{d2} are each independently a substituted or unsubstituted, straight or branched chain alkyl group, alkoxy group or alkoxycarbonyl group having a carbon number of 1 to 12; a substituted or unsubstituted aromatic hydrocarbon group having a carbon number of 6 to 12; a halogen atom; a halogenated alkyl group having a carbon number of 1 to 4; a nitro group; or a ring structure obtained by combining two or more of these groups. k6 and k7 are each independently an integer of 0 to 5. When there are a plurality of R^{d1} and a plurality of R^{d2}, a plurality of R^{d1} and a plurality of R^{d2} may be each identical or different.

In the above formula (X-6), R^{e1} and R^{e2} are each independently a halogen atom; a substituted or unsubstituted straight or branched chain alkyl group having a carbon number of 1 to 12; or a substituted or unsubstituted aromatic hydrocarbon group having a carbon number of 6 to 12. k8 and k9 are each independently an integer of 0 to 4.

Specific examples of the radiolytic onium cation include, but are not limited thereto, the structures represented by formulas (1-2-1) to (Jan. 2, 1954).

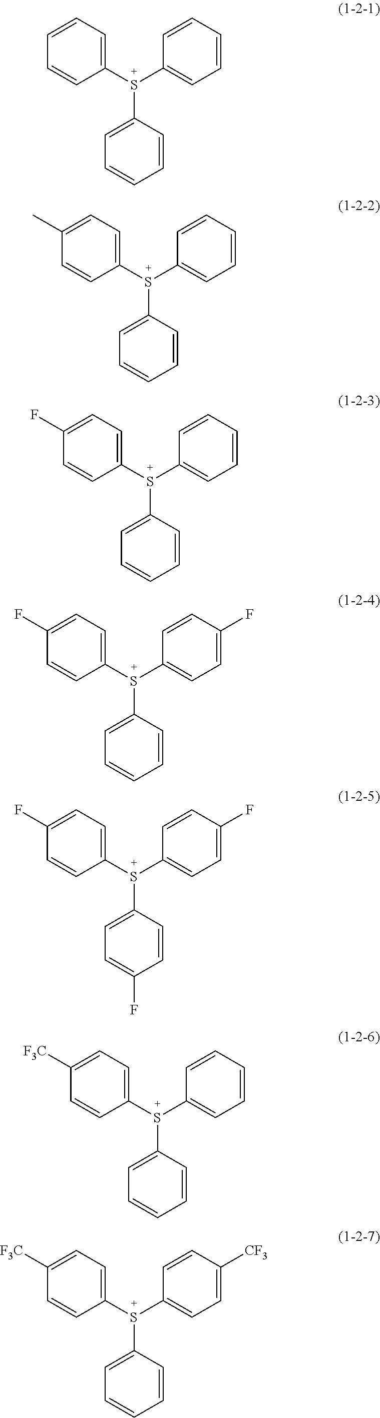

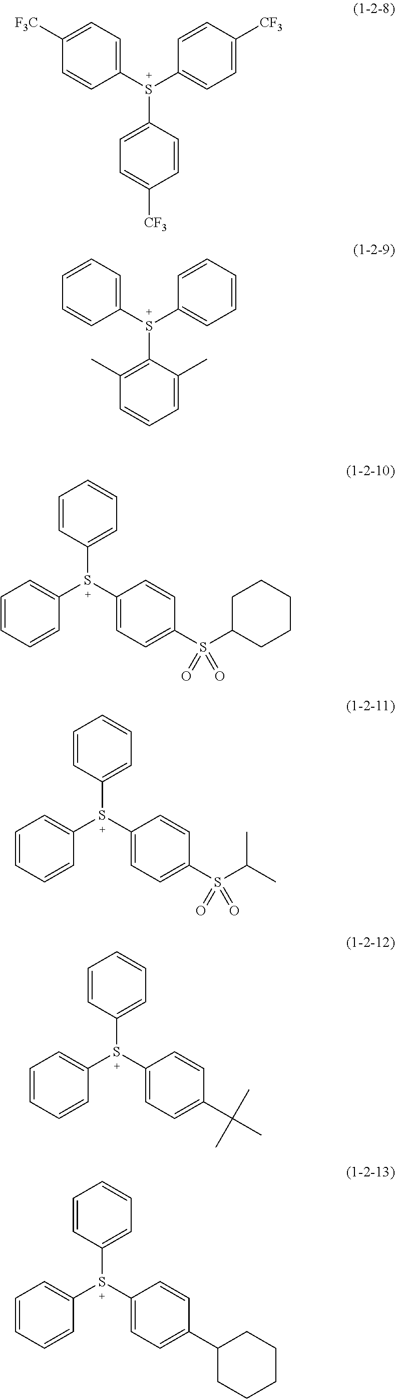

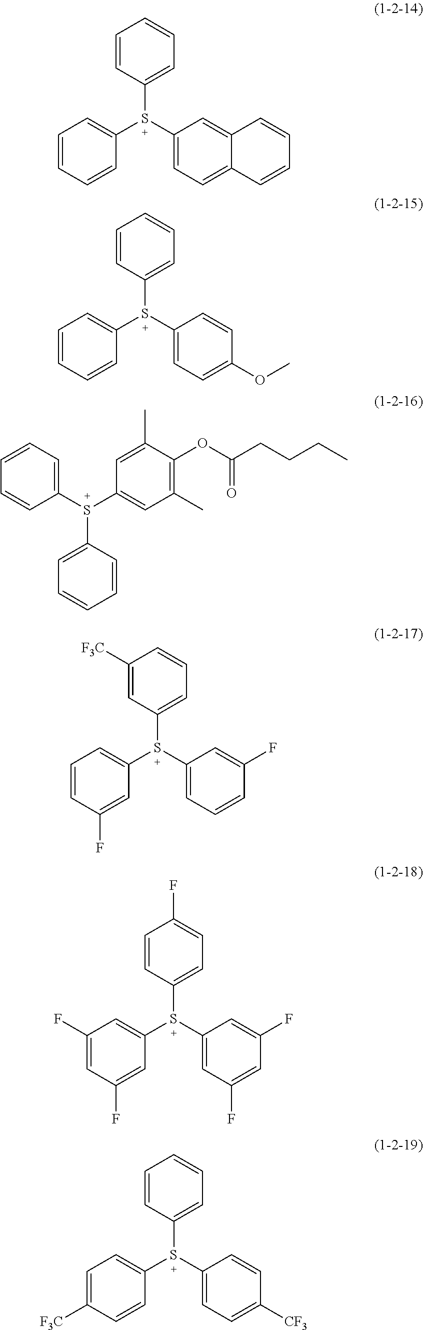

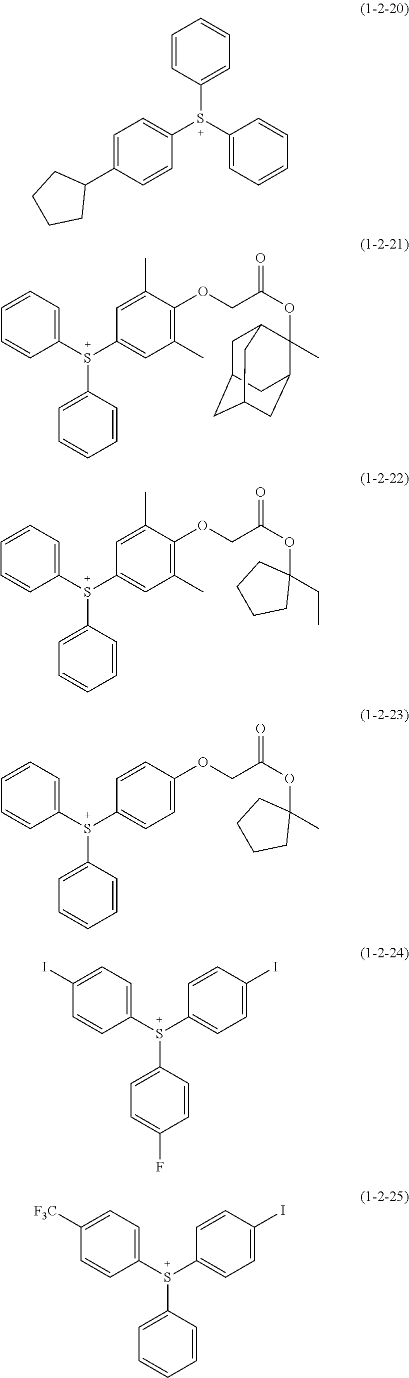

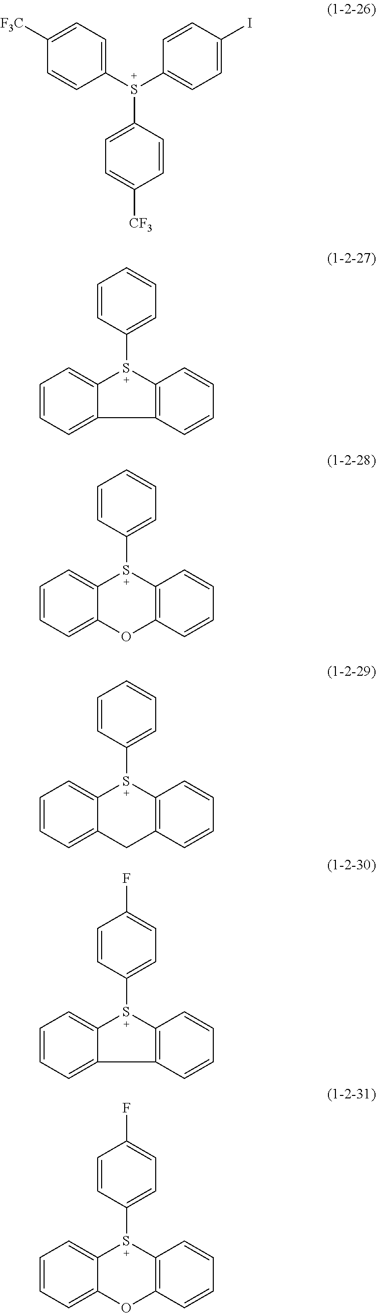

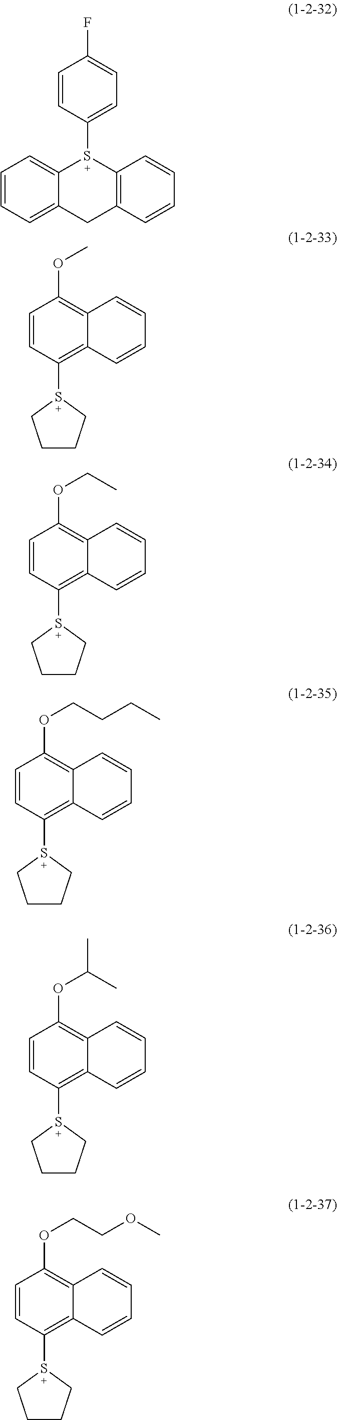

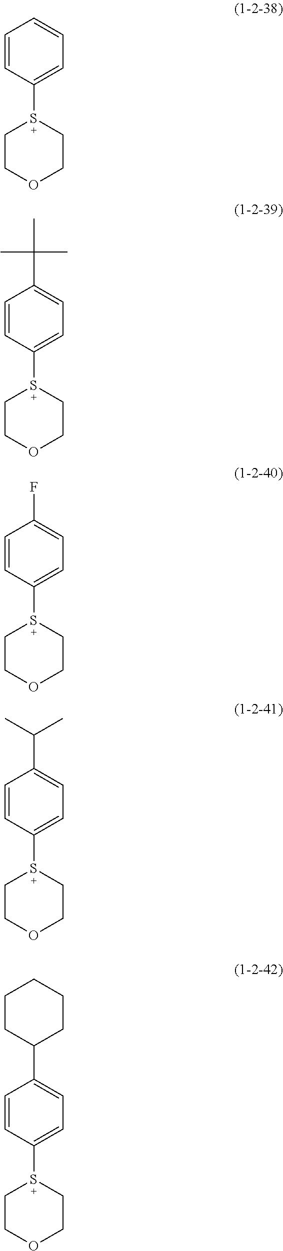

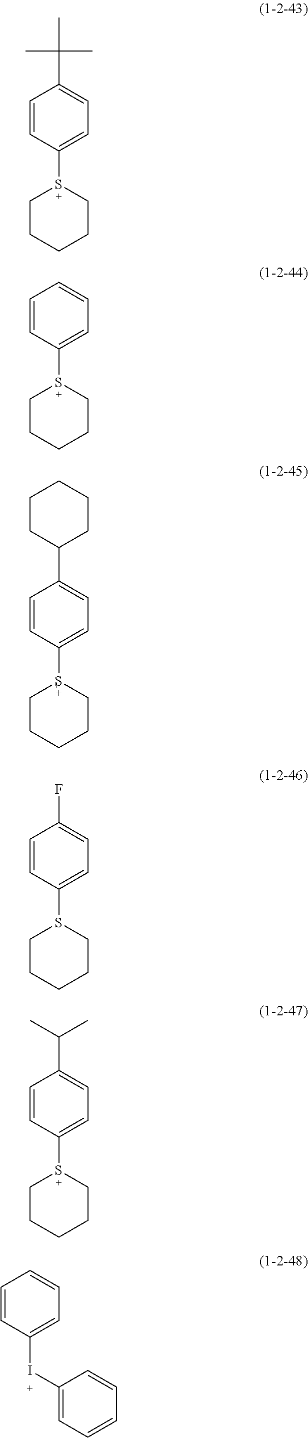

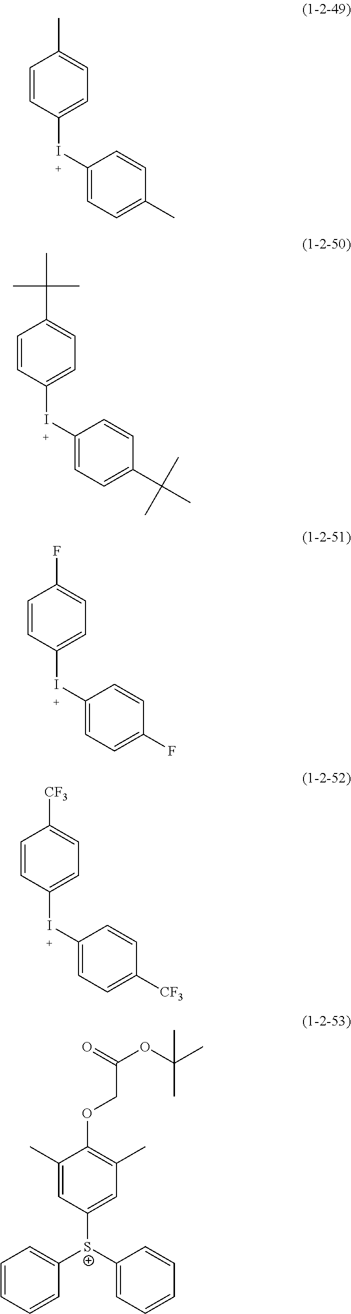

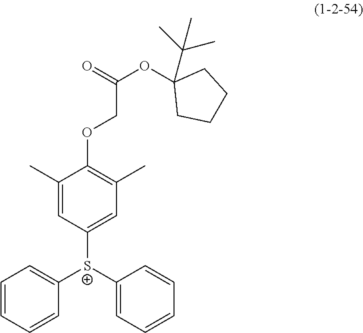 [SMILES: Cc1cc([S+](c2ccccc2)c2ccccc2)cc(C)c1OCC(=O)OC1(C(C)(C)C)CCCC1]

The onium salt (1) is formed of an arbitrary combination of an anion moiety in the above formula (1) and the aforementioned monovalent onium cation. Examples of the onium salt (1) are not particularly limited, but include structures represented by formulas (1-1) to (1-36).

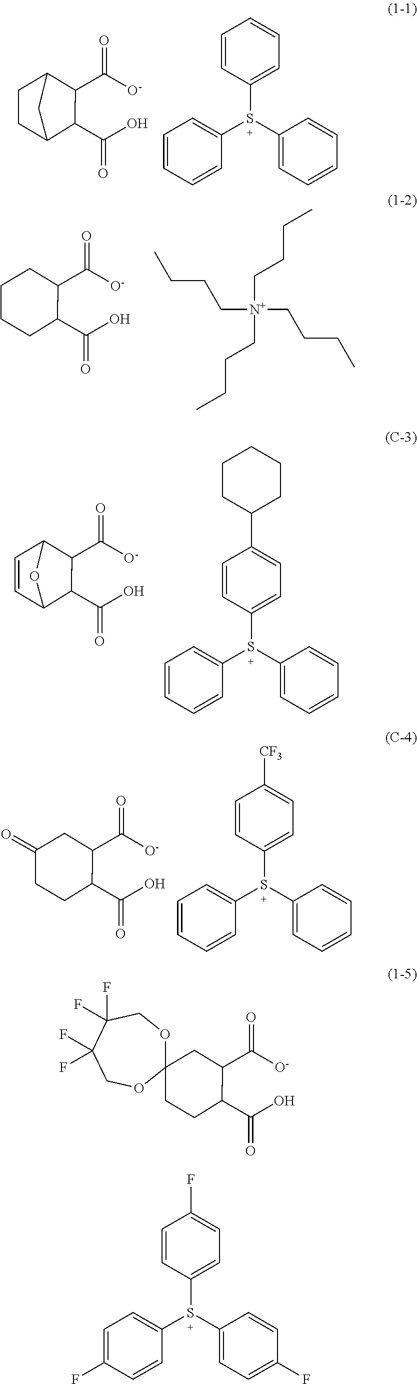

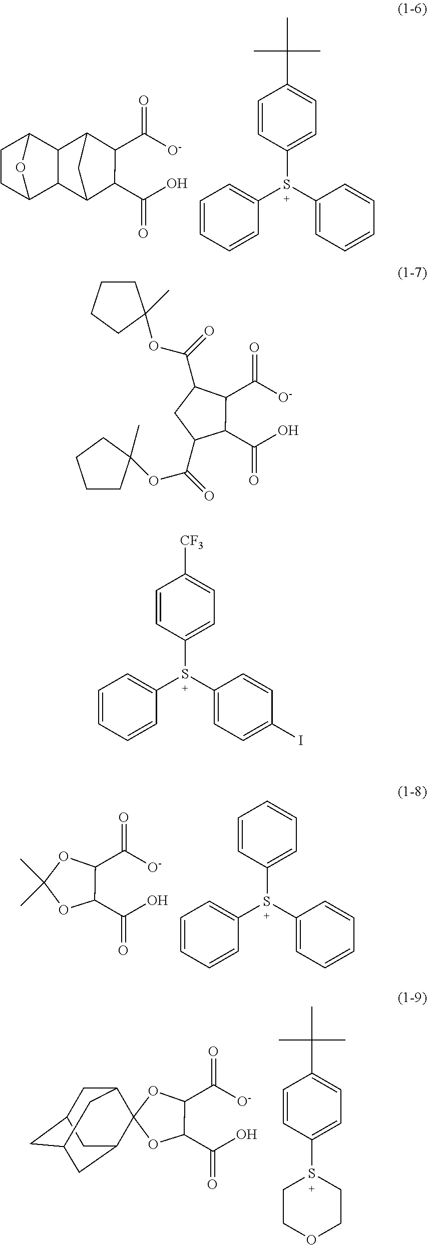

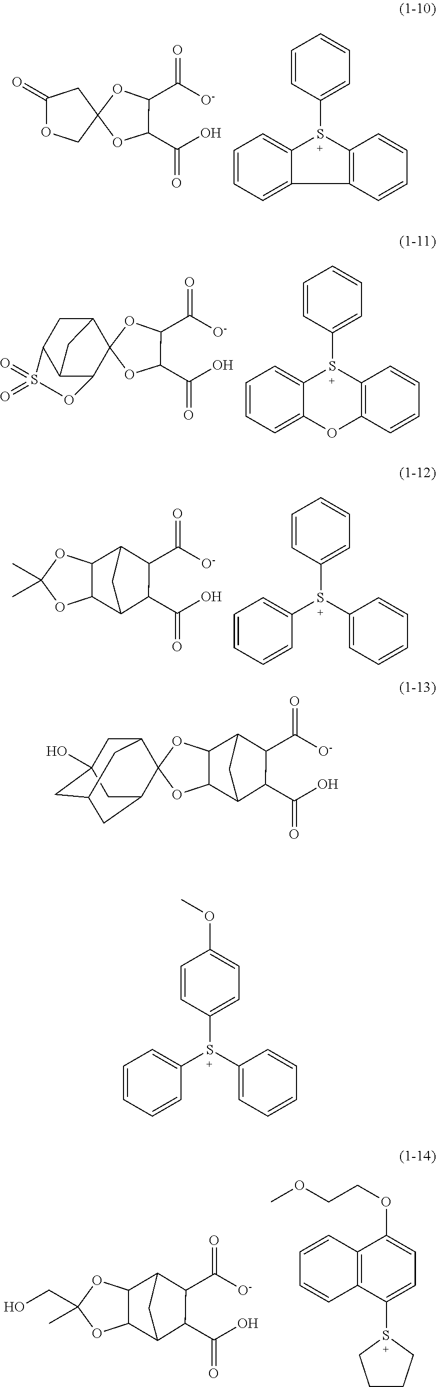

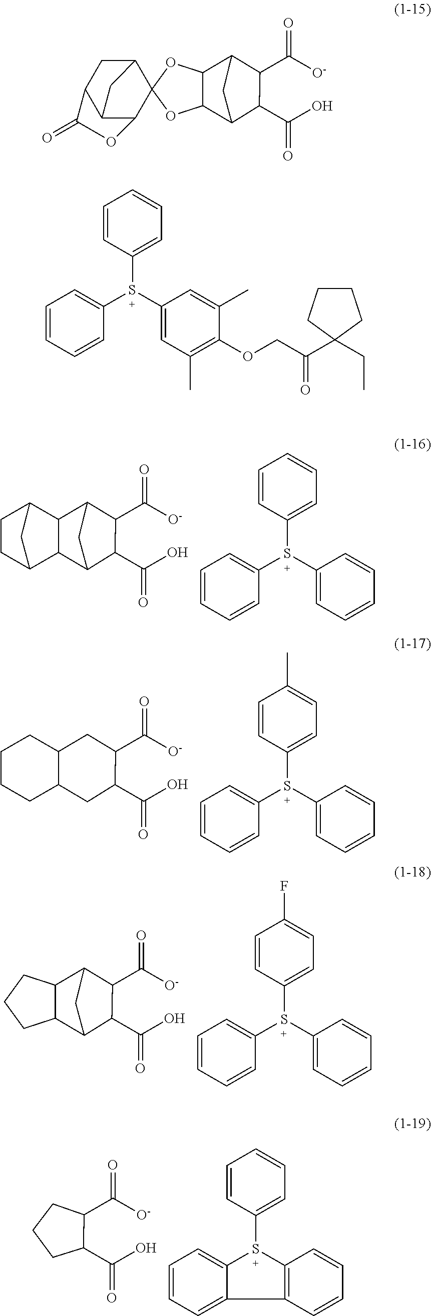

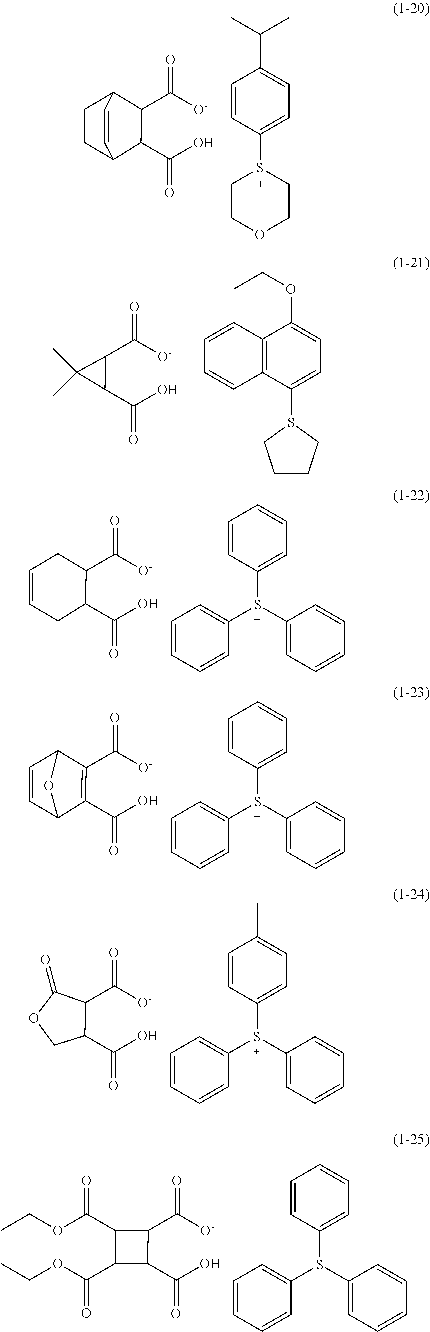

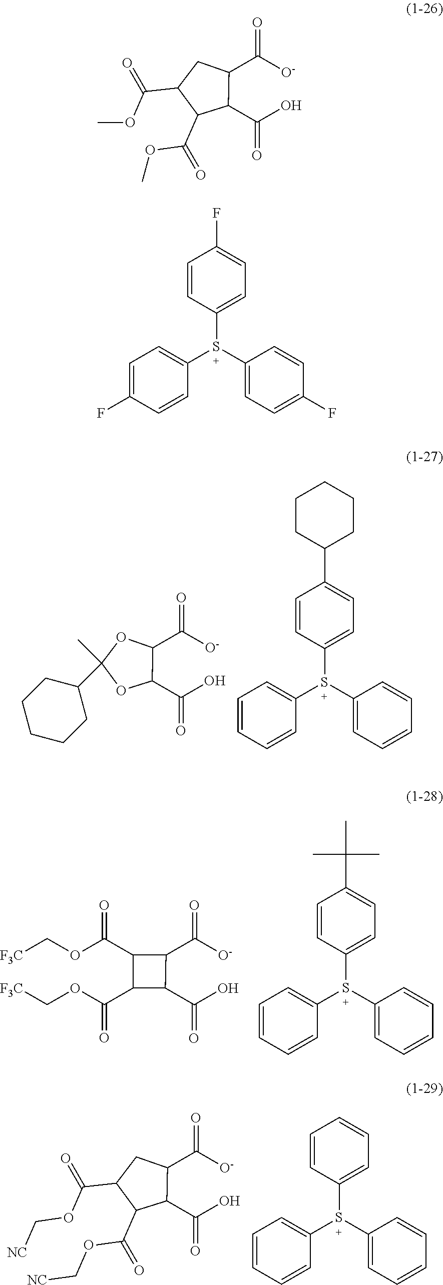

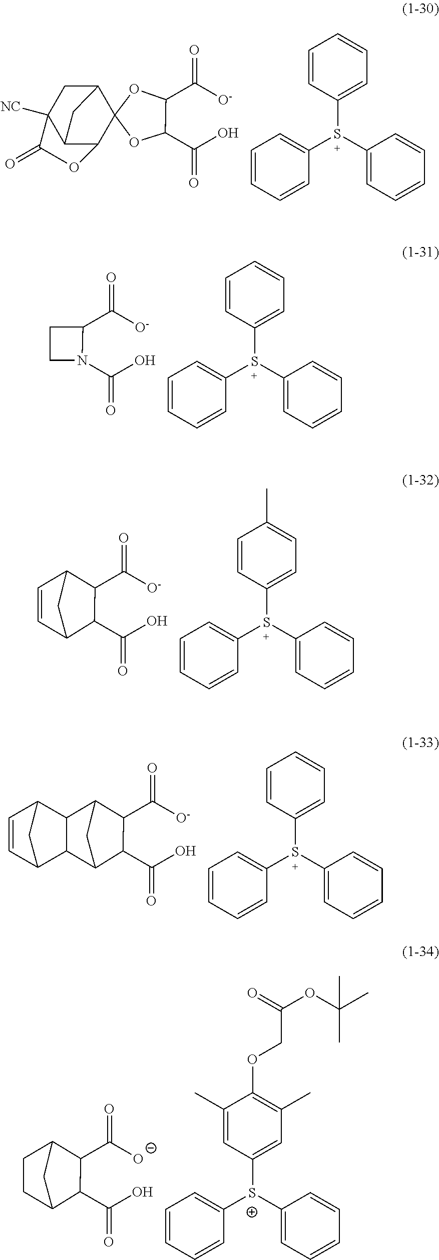

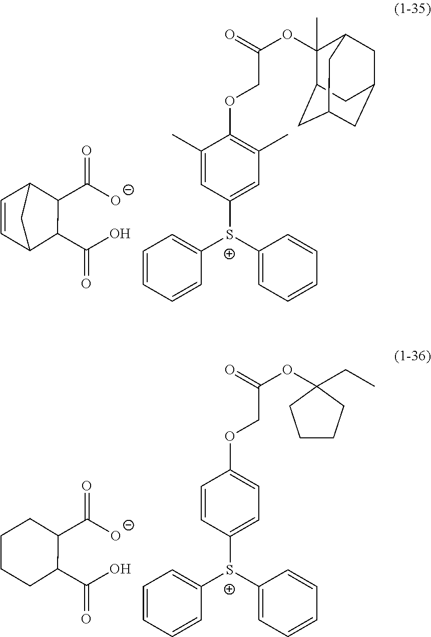 [SMILES: O=C([O-])C1C2C=CC(C2)C1C(=O)O ; Cc1cc([S+](c2ccccc2)c2ccccc2)cc(C)c1OCC(=O)OC1(C)C2CC3CC(C2)CC1C3 ; O=C([O-])C1CCCCC1C(=O)O ; CCC1(OC(=O)COc2ccc([S+](c3ccccc3)c3ccccc3)cc2)CCCC1]

The content of the onium salt (1) in the radiation-sensitive composition is appropriately selected according to the type of the polymer to be used, the exposure conditions, the required sensitivity, and the type and content of the radiation-sensitive acid generator described later.

The lower limit of the content of the onium salt (1) (when plural kinds of onium salts are used in combination, the total content thereof) is preferably 0.1 parts by mass, more preferably 0.3 parts by mass, and still more preferably 0.5 parts by mass with respect to 100 parts by mass of the polymer described later. The upper limit of the content is preferably 30 parts by mass, more preferably 28 parts by mass, and still more preferably 25 parts by mass. When the content of the onium salt (1) is adjusted in the above range, excellent sensitivity, LWR performance, DOF performance, pattern rectangularity, CDU performance, pattern circularity, EL performance, and pattern collapse resistance as described above can be exhibited when a resist pattern is formed.

### (Method for Synthesizing Onium Salt (1))

According to the following scheme, a desired onium salt (1) can be synthesized by using a dicarboxylic acid form (i) having an anion moiety of the desired onium salt (1) as a raw material, and reacting the dicarboxylic acid form with an onium cation halide corresponding to an onium cation moiety to obtain a carboxylate.

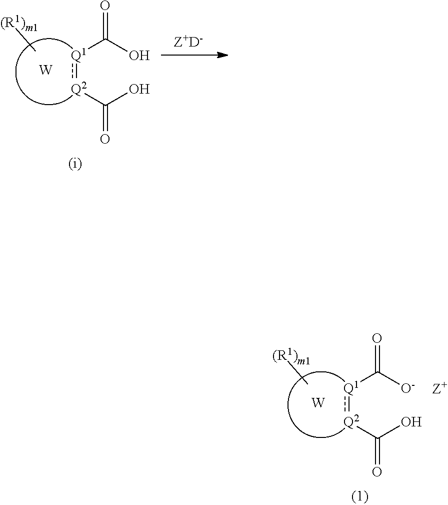

In the scheme, Q¹, Q², W, the binding mode between Q¹ and Q² in the formula, R¹, Z⁺, and m₁ have the same meaning as in the above formula (1), and D⁻ is a halide ion.

### (Polymer)

The polymer is an aggregate of polymerization chains having a structural unit (hereinafter, also referred to as “structural unit (I)”) containing an acid-dissociable group (hereinafter, this polymer is also referred to as “base polymer”). The “acid-dissociable group” refers to a group that substitutes for a hydrogen atom of a carboxy group, a phenolic hydroxyl group, an alcoholic hydroxyl group, a sulfo group, or the like, and is dissociated by the action of an acid. The radiation-sensitive composition is excellent in pattern-forming performance because the polymer has the structural unit (I).

In addition to the structural unit (I), the base polymer preferably has a structural unit (II) containing at least one selected from the group consisting of a lactone structure, a cyclic carbonate structure, and a sultone structure described later, and may have another structural unit other than the structural units (I) and (II). Each of the structural units will be described below.

### [Structural Unit (I)]

The structural unit (I) contains an acid-dissociable group. The structural unit (I) is not particularly limited as long as it contains an acid-dissociable group. Examples of such a structural unit (I) include a structural unit having a tertiary alkyl ester moiety, a structural unit having a structure obtained by substituting the hydrogen atom of a phenolic hydroxyl group with a tertiary alkyl group, and a structural unit having an acetal bond. From the viewpoint of improving the pattern-forming performance of the radiation-sensitive composition, a structural unit represented by formula (3) (hereinafter also referred to as a “structural unit (I-1)”) is preferred.

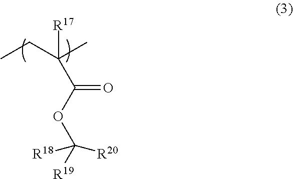

(In the above formula (2), R¹⁷ is a hydrogen atom, a fluorine atom, a methyl group, or a trifluoromethyl group, R⁸ is a a monovalent hydrocarbon group having 1 to 20 carbon atoms, R¹⁹ and R²⁰ are each independently a monovalent chain hydrocarbon group having 1 to 10 carbon atoms or a monovalent alicyclic hydrocarbon group having 3 to 20 carbon atoms or R¹⁹ and R²⁰ taken together represent a divalent alicyclic group having 3 to 20 carbon atoms together with the carbon atom to which R¹⁹ and R²⁰ are bonded.

From the viewpoint of copolymerizability of a monomer that will give the structural unit (I-1), R¹⁷ is preferably a hydrogen atom or a methyl group, more preferably a methyl group.

Examples of the monovalent hydrocarbon group having 1 to 20 carbon atoms represented by R¹⁸ include a monovalent chain hydrocarbon group having 1 to 10 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon groups having 1 to 10 carbon atoms represented by R¹⁸ to R²⁰ include monovalent linear or branched saturated hydrocarbon groups having 1 to 10 carbon atoms and monovalent linear or branched unsaturated hydrocarbon groups having 1 to 10 carbon atoms.

As the monovalent alicyclic hydrocarbon groups having 3 to 20 carbon atoms represented by R¹⁸ to R²⁰, the monovalent alicyclic hydrocarbon groups having 3 to 20 carbon atoms in R¹ of the above formula (1) can be suitably employed.

As the monovalent aromatic hydrocarbon group having 6 to 20 carbon atoms represented by R¹⁸, the monovalent aromatic hydrocarbon groups having 6 to 20 carbon atoms in R¹ in the above formula (1) can be suitably employed.

R⁸ is preferably a linear or branched saturated hydrocarbon group having 1 to 10 carbon atoms or an alicyclic hydrocarbon group having 3 to 20 carbon atoms.

The divalent alicyclic group having 3 to 20 carbon atoms formed by R¹⁹ and R¹⁰ together with the carbon atom to which R¹⁹ and R¹⁰ are bonded is not particularly limited as long as it is a group obtained by removing two hydrogen atoms from the same carbon atom constituting a carbon ring of a monocyclic or polycyclic alicyclic hydrocarbon having the above-described carbon number. The divalent alicyclic group having 3 to 20 carbon atoms may either be a monocyclic hydrocarbon group or a polycyclic hydrocarbon group. The polycyclic hydrocarbon group may either be a bridged alicyclic hydrocarbon group or a condensed alicyclic hydrocarbon group and may either be a saturated hydrocarbon group or an unsaturated hydrocarbon group. It is to be noted that the condensed alicyclic hydrocarbon group refers to a polycyclic alicyclic hydrocarbon group in which two or more alicyclic rings share their sides (bond between two adjacent carbon atoms).

When the monocyclic alicyclic hydrocarbon group is a saturated hydrocarbon group, preferred examples thereof include a cyclopentanediyl group, a cyclohexanediyl group, a cycloheptanediyl group, and a cyclooctanediyl group. When the monocyclic alicyclic hydrocarbon group is an unsaturated hydrocarbon group, preferred examples thereof include a cyclopentenediyl group, a cyclohexenediyl group, a cycloheptenediyl group, a cyclooctenediyl group, and a cyclodecenediyl group. The polycyclic alicyclic hydrocarbon group is preferably a bridged alicyclic saturated hydrocarbon group, and preferred examples thereof include a bicyclo[2.2.1]heptane-2,2-diyl group (norbornane-2,2-diyl group), a bicyclo[2.2.2]octane-2,2-diyl group, and a tricyclo[3.3.1.1^{3,7}]decane-2,2-diyl group (adamantane-2,2-diyl group).

Among them, R¹⁸ is preferably an alkyl group having 1 to 4 carbon atoms, and the alicyclic structure formed by R¹⁹ and R²⁰ combined together and a carbon atom to which they are bonded is preferably a polycyclic or monocyclic cycloalkane structure.

Examples of the structural unit (I-1) include structural units represented by formulas (3-1) to (3-8) (hereinafter also referred to as “structural units (I-1-1) to (I-1-8)”).

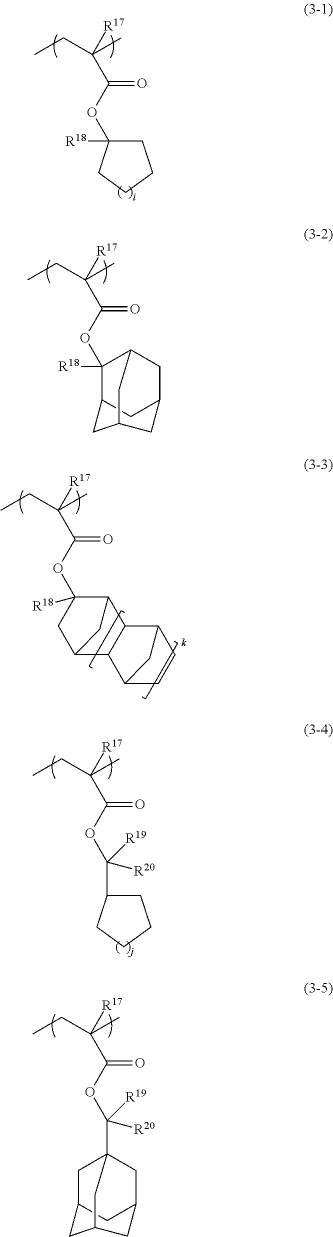

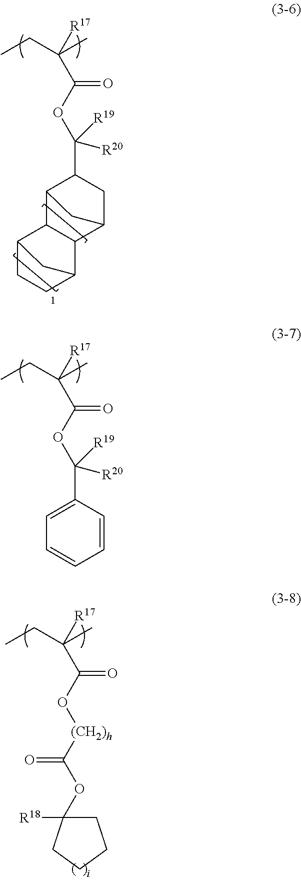

In the above formulas (3-1) to (3-8), R¹⁷ to R²⁰ have the same meaning as in the above formula (3), h is an integer of 1 to 4, i and j are each independently an integer of 1 to 4, and k and l are each 0 or 1.

i and j are preferably 1. R¹⁸ is preferably a methyl group, an ethyl group, an isopropyl group, or a cyclopentyl group. R¹⁹ and R²⁰ are each preferably a methyl group, or an ethyl group.

The base polymer may contain one type or a combination of two or more types of the structural units (I).

The lower limit of the content (total content, if multiple types are included) of the structural unit (I) is preferably 10 mol %, more preferably 20 mol %, even more preferably 30 mol %, particularly preferably 35 mol % with respect to the total amount of the structural units constituting the base polymer. The upper limit of the content is preferably 90 mol %, more preferably 80 mol %, even more preferably 70 mol %, particularly preferably 60 mol %. When the content of the structural unit (I) is set to fall within the above range, the pattern-forming performance of the radiation-sensitive composition can further be improved.

### [Structural Unit (II)]

The structural unit (II) is a structural unit including at least one selected from the group consisting of a lactone structure, a cyclic carbonate structure and a sultone structure. The solubility of the base polymer into a developer can be adjusted by further introducing the structural unit (II). As a result, the radiation-sensitive composition can provide improved lithography properties such as the resolution. The adhesion between a resist pattern formed from the base polymer and a substrate can also be improved.

Examples of the structural unit (II) include structural units represented by formulae (T-1) to (T-11).

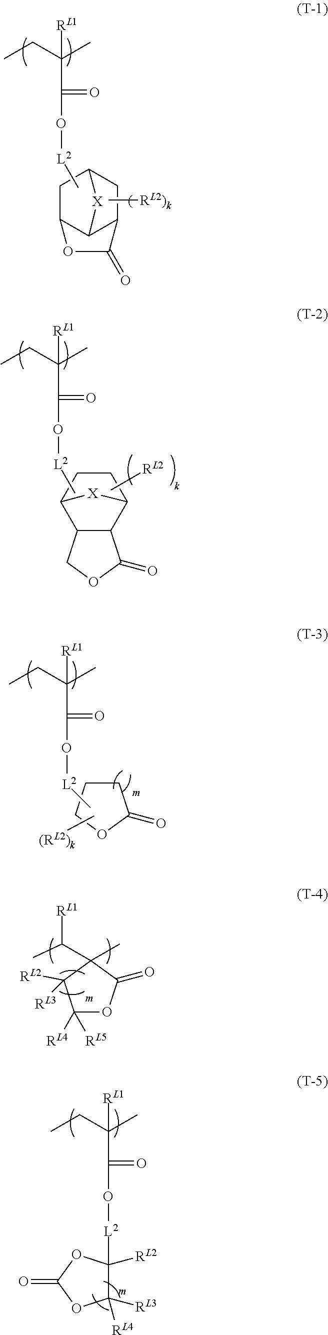

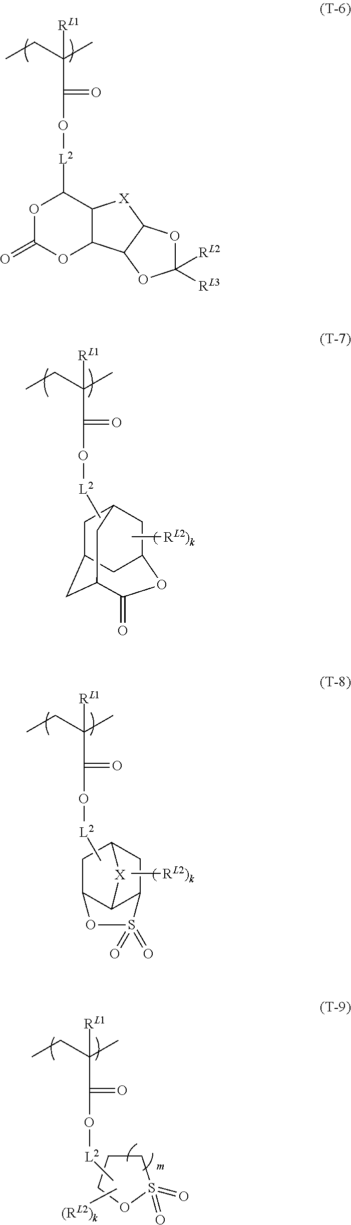

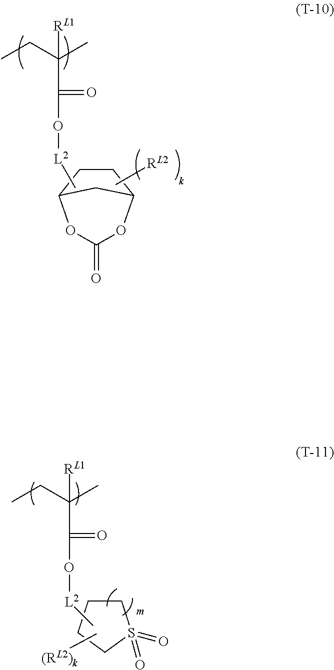

In the above formulae, R^{L1} is a hydrogen atom, a fluorine atom, a methyl group, or a trifluoromethyl group; R^{L2} to R^{L5} are each independently a hydrogen atom, an alkyl group having a carbon number of 1 to 4, a cyano group, a trifluoromethyl group, a methoxy group, a methoxycarbonyl group, a hydroxy group, a hydroxymethyl group, or a dimethylamino group; R^{L4} and R^{L5} may be a divalent alicyclic group having a carbon number of 3 to 8, which is obtained by combining R^{L4} and R^{L5} with the carbon atom to which they are bound. L² is a single bond, or a divalent linking group; X is an oxygen atom or a methylene group; k is an integer of 0 to 3; and m is an integer of 1 to 3.

Examples of the divalent alicyclic group having 3 to 8 carbon atoms in which R^{L4} and R^{L5} are combined with each other and which is constituted by R^{L4} and R^{L5} together with the carbon atoms to which they are bonded include groups having 3 to 8 carbon atoms among divalent alicyclic groups having 3 to 20 carbon atoms in which R¹⁹ and R²⁰ in the above formula (3) are combined with each other and which is constituted by R¹⁹ and R²⁰ together with the carbon atoms to which they are bonded. One or more hydrogen atoms on the alicyclic group may be substituted with a hydroxy group.

Examples of the divalent linking group represented by L² as described above include a divalent straight or branched chain hydrocarbon group having a carbon number of 1 to 10; a divalent alicyclic hydrocarbon group having a carbon number of 4 to 12; and a group composed of one or more of the hydrocarbon group thereof and at least one group of —CO—, —O—, —NH— and —S—.

Among them, the structural unit (II) is preferably a group having a lactone structure, more preferably a group having a norbornane lactone structure, and further preferably a group derived from a norbornane lactone-yl (meth)acrylate.

The lower limit of the content ratio of the structural unit (II) is preferably 10 mol %, more preferably 20 mol %, still more preferably 30 mol %, and particularly preferably 35 molo with respect to all structural units constituting the base polymer. The upper limit of the content ratio is preferably 90 mol %, more preferably 80 mol %, still more preferably 70 mol %, and particularly preferably 65 mol %. By adjusting the content by percent of the structural unit D within the ranges, the radiation-sensitive composition can provide improved lithography properties such as the resolution. The adhesion between the formed resist pattern and the substrate can also be improved.

### [Structural Unit (III)]

The base polymer optionally has another structural unit in addition to the structural units (I) and (II). Another structural unit includes a structural unit (III) containing a polar group (excluding those corresponding to the structural unit (II)). When the base polymer further has a structural unit (III), solubility in the developer can be adjusted. As a result, lithographic performance such as resolution of the radiation-sensitive composition can be improved. Examples of the polar group include a hydroxy group, a carboxy group, a cyano group, a nitro group, and a sulfonamide group. Among them, a hydroxy group and a carboxy group are preferable, and a hydroxy group is more preferable.

Examples of the structural unit (III) include structural units represented by formulas.

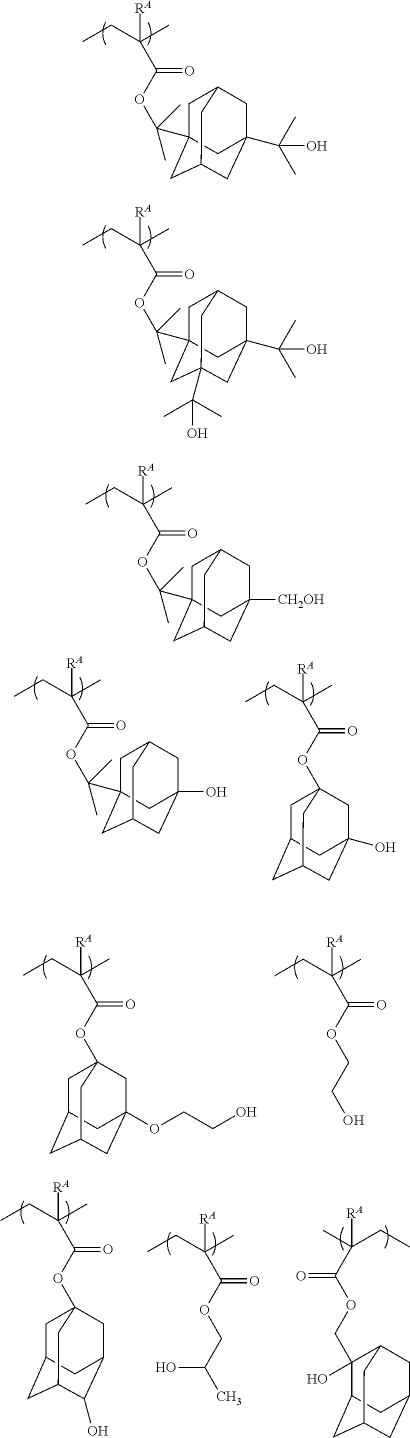

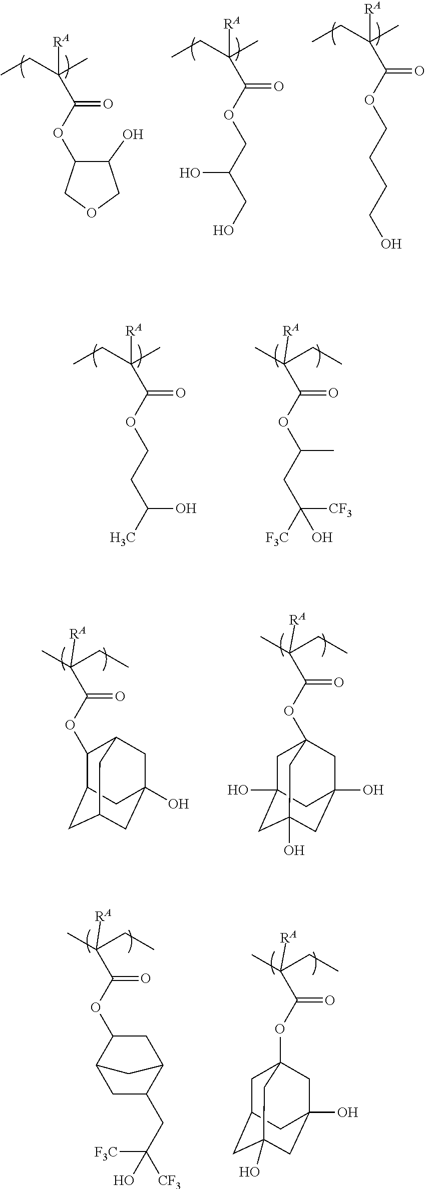

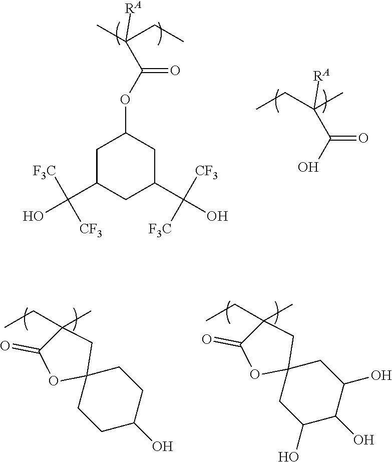

In the above formulas, RA is a hydrogen atom, a fluorine atom, a methyl group, or a trifluoromethyl group.

When the base polymer has the structural unit (III) having a polar group, the lower limit of the content ratio of the structural unit (III) is preferably 2 mol %, more preferably 5 mol %, still more preferably 8 mol % with respect to all structural units constituting the base polymer. The upper limit of the content ratio is preferably 40 mol %, more preferably 30 mol %, and still more preferably 25 mol %. When the content of the structural unit having a polar group is set to fall within the above range, the radiation-sensitive composition can provide further improved lithography properties such as the resolution.

### [Structural Unit (IV)]

The base polymer optionally has, as another structural unit, a structural unit having a phenolic hydroxyl group (hereinafter, also referred to as “structural unit (IV)”), in addition to the structural unit (III) having a polar group. The structural unit (IV) contributes to an improvement in etching resistance and an improvement in a difference in solubility of a developer (dissolution contrast) between an exposed part and a non-exposed part. In particular, the structural unit (IV) can be suitably applied to pattern formation using exposure with a radioactive ray having a wavelength of 50 nm or less, such as an electron beam or EUV. In this case, the polymer preferably has the structural unit (I) together with the structural unit (IV).

The structural unit having a phenolic hydroxyl group is represented by, for example, formulas (4-1) to (4-6).

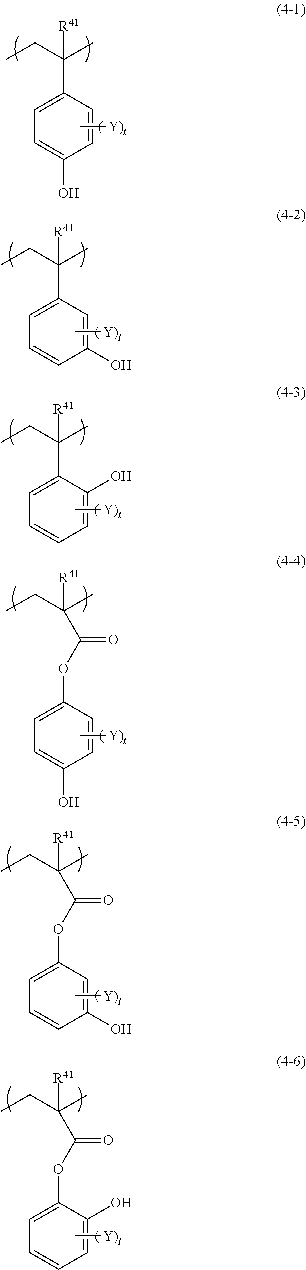

In the above formulas (4-1) to (4-6), R⁴¹ is independently at each occurrence a hydrogen atom, a fluorine atom, a methyl group, or a trifluoromethyl group. Y is a halogen atom, a trifluoromethyl group, a cyano group, an alkyl or alkoxy group having 1 to 6 carbon atoms, or an acyl, acyloxy, or alkoxycarbonyl group having 2 to 7 carbon atoms. When there are a plurality of Y's, the plurality of Y's are the same or different from each other. t is an integer of 0 to 4.

In the case of obtaining the structural unit (IV), it is preferable to obtain the structural unit (IV) by polymerizing the monomer in a state where the phenolic hydroxyl group is protected by a protecting group such as an alkali-dissociable group (e.g., an acyl group) during polymerization, and then deprotecting the polymerized product by hydrolysis. The monomer may be polymerized without protecting the phenolic hydroxyl group.

In the case of a polymer for exposure with a radioactive ray having a wavelength of 50 nm or less, the lower limit of the content of the structural unit (IV) is preferably 10 mol %, more preferably 20 mol %, with respect to the total amount of structural units constituting the polymer. The upper limit of the content is preferably 70 mol %, more preferably 60 mol %.

### [Other Structural Unit]

The base polymer may contain, as a structural unit other than the structural units listed above, a structural unit represented by a formula (6) below and containing an alicyclic structure.

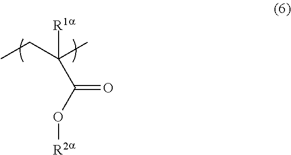

In the formula (6), R^{1α} represents a hydrogen atom, a fluorine atom, a methyl group, or a trifluoromethyl group, and R^{2α} represents a monovalent alicyclic hydrocarbon group having 3 to 20 carbon atoms.

In the formula (6), as the monovalent alicyclic hydrocarbon group having 3 to 20 carbon atoms represented by R^{2α}, the monovalent alicyclic hydrocarbon groups having 3 to 20 carbon atoms represented by R¹ in the above formula (1) can be suitably employed.

When the base polymer contains the structural unit having an alicyclic structure, the lower limit of the content ratio of the structural unit having an alicyclic structure is preferably 2 mol %, more preferably 5 mol %, and still more preferably 8 mol %, with respect to all structural units constituting the base polymer. The upper limit of the content ratio is preferably 30 mol %, more preferably 20 mol %, and still more preferably 15 mol %.

### (Synthesis Method of Base Polymer)

For example, the base polymer can be synthesized by performing a polymerization reaction of each monomer for providing each structural unit with a radical polymerization initiator or the like in a suitable solvent.

Examples of the radical polymerization initiator include an azo-based radical initiator, including azobisisobutyronitrile (AIBN), 2,2′-azobis(4-methoxy-2,4-dimethylvaleronitrile), 2,2′-azobis(2-cyclopropylpropanenitrile), 2,2′-azobis(2,4-dimethylvaleronitrile), and dimethyl 2,2′-azobisisobutyrate; and peroxide-based radical initiator, including benzoyl peroxide, t-butyl hydroperoxide, and cumene hydroperoxide. Among them, AIBN or dimethyl 2,2′-azobisisobutyrate is preferred, and AIBN is more preferred. The radical initiator may be used alone, or two or more radical initiators may be used in combination.

Examples of the solvent used for the polymerization reaction include
alkanes including n-pentane, n-hexane, n-heptane, n-octane, n-nonane, and n-decane;
cycloalkanes including cyclohexane, cycloheptane, cyclooctane, decalin, and norbornane;
aromatic hydrocarbons including benzene, toluene, xylene, ethylbenzene, and cumene;
halogenated hydrocarbons including chlorobutanes, bromohexanes, dichloroethanes, hexamethylenedibromide, and chlorobenzenes;
saturated carboxylate esters, including ethyl acetate, n-butyl acetate, i-butyl acetate, and methyl propionate;
cyclic esters such as γ-butyrolactone
ketones including acetone, methyl ethylketone, 2-butanone, 4-methyl-2-pentanone, and 2-heptanone;
ethers including tetrahydrofuran, dimethoxyethanes, diethoxyethanes, and polyhydric alcohol partial ethers; and
alcohols including methanol, ethanol, 1-propanol, 2-propanol, and 4-methyl-2-pentanol. The solvent used for the polymerization reaction may be used alone, or two or more solvents may be used in combination.

The reaction temperature of the polymerization reaction is typically from 40° C. to 150° C., and preferably from 50° C. to 120° C. The reaction time is typically from 1 hour to 48 hours, and preferably from 1 hour to 24 hours.

The molecular weight of the base polymer is not particularly limited, but the lower limit of the weight average molecular weight (Mw) as determined by Gel Permeation Chromatography (GPC) relative to standard polystyrene is preferably 2,000, more preferably 3,000, still more preferably 4,000. The upper limit of the Mw is preferably 30,000, more preferably 20,000, and still more preferably 10,000. When the Mw of the base polymer is adjusted in the above range, good heat resistance and developability can be obtained in the resulting resist film.

For the base polymer as a base polymer, the ratio of Mw to the number average molecular weight (Mn) as determined by GPC relative to standard polystyrene (Mw/Mn) is typically not less than 1 and not more than 5, preferably not less than 1 and not more than 3, and more preferably not less than 1 and not more than 2.

The Mw and Mn of the polymer in the specification are amounts measured by using Gel Permeation Chromatography (GPC) with the condition as described below.
GPC column: two G2000HXL, one G3000HXL, and one G4000HXL (all manufactured from Tosoh Corporation)
Column temperature: 40° C.
Eluting solvent: tetrahydrofuran
Flow rate: 1.0 mL/min
Sample concentration: 1.0% by mass
Sample injection amount: 100 μL
Detector: Differential Refractometer
Reference material: monodisperse polystyrene

The content ratio of the base polymer is preferably 50 mass % or more, more preferably 55 mass % or more, and still more preferably 60 mass % or more with respect to the total solid content of the radiation-sensitive composition.

### (Other Polymer)

The radiation-sensitive composition according to the present embodiment may contain, as another polymer, a polymer having a higher content rate by mass of fluorine atoms than the content rate of the base polymer (hereinafter, also referred to as a “higher fluorine-content polymer”). When the radiation-sensitive composition contains the high fluorine-content polymer, the high fluorine-content polymer can be localized in the surface layer of a resist film compared to the base polymer, which as a result makes it possible to enhance the water repellency of the surface of the resist film during immersion exposure or to perform surface modification of the resist film during EUV exposure or control of the distribution of the composition in the film.

The high fluorine-content polymer preferably has, for example, a structural unit represented by formula (5) (hereinafter, also referred to as “structural unit (V)”), and may have the structural unit (I) or the structural unit (III) in the base polymer as necessary.

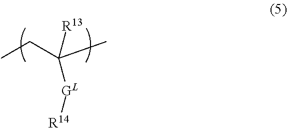

In the above formula (5), R¹³ is a hydrogen atom, a methyl group, or a trifluoromethyl group; G^{L} is a single bond, an alkanediyl group having 1 to 5 carbon atoms, an oxygen atom, a sulfur atom, —COO—, —SO₂ONH—, —CONH—, —OCONH—, or a combination thereof. R¹⁴ is a monovalent fluorinated chain hydrocarbon group having a carbon number of 1 to 20, or a monovalent fluorinated alicyclic hydrocarbon group having a carbon number of 3 to 20.

As R¹³ as described above, in terms of the copolymerizability of monomers resulting in the structural unit (V), a hydrogen atom or a methyl group is preferred, and a methyl group is more preferred.

As G^{L} as described above, in terms of the copolymerizability of monomers resulting in the structural unit (V), a single bond or —COO— is preferred, and —COO— is more preferred.

Example of the monovalent fluorinated chain hydrocarbon group having a carbon number of 1 to 20 represented by R¹⁴ as described above includes a group in which a part of or all of hydrogen atoms in the straight or branched chain alkyl group having a carbon number of 1 to 20 is/are substituted with a fluorine atom.

Example of the monovalent fluorinated alicyclic hydrocarbon group having a carbon number of 3 to 20 represented by R¹⁴ as described above includes a group in which a part of or all of hydrogen atoms in the monocyclic or polycyclic hydrocarbon group having a carbon number of 3 to 20 is/are substituted with a fluorine atom.

The R¹⁴ as described above is preferably a fluorinated chain hydrocarbon group, more preferably a fluorinated alkyl group, and further preferably 2,2,2-trifluoroethyl group, 2,2,3,3,3-pentafluoropropyl group, 1,1,1,3,3,3-hexafluoropropyl group and 5,5,5-trifluoro-1,1-diethylpentyl group.

When the high fluorine-content polymer has the structural unit (V), the lower limit of the content ratio of the structural unit (V) is preferably 50 mol %, more preferably 60 mol %, and still more preferably 70 mol % with respect to all structural units constituting the high fluorine-content polymer. The upper limit of the content ratio is preferably 95 mol %, more preferably 90 mol, and still more preferably 85 mol %. When the content of the structural unit (V) is set to fall within the above range, the content by mass of fluorine atoms of the high fluorine-content polymer can more appropriately be adjusted to further promote the localization of the high fluorine-content polymer in the surface layer of a resist film, as a result, the water repellency of the resist film during immersion exposure can be further improved.

The high fluorine-content polymer may have a fluorine atom-containing structural unit represented by formula (f-2) (hereinafter, also referred to as a “structural unit (VI)”) in addition to or in place of the structural unit (V). When the high fluorine-content polymer has the structural unit (VI), solubility in an alkaline developing solution is improved, and therefore generation of development defects can be prevented.

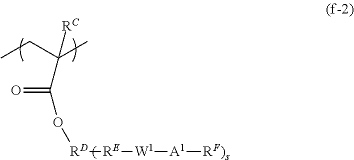

The structural unit (VI) is classified into two groups: a unit having an alkali soluble group (x); and a unit having a group (y) in which the solubility into the alkaline developing solution is increased by the dissociation by alkali (hereinafter, simply referred as an “alkali-dissociable group”). In both cases of (x) and (y), R^{C} in the above formula (f-2) is a hydrogen atom, a fluorine atom, a methyl group, or a trifluoromethyl group; R^{D} is a single bond, a hydrocarbon group having a carbon number of 1 to 20 with the valency of (s+1), a structure in which an oxygen atom, a sulfur atom, —NR^{dd}—, a carbonyl group, —COO—, —OCO—, or —CONH— is connected to the terminal on R^{E} side of the hydrocarbon group, or a structure in which a part of hydrogen atoms in the hydrocarbon group is substituted with an organic group having a hetero atom; R^{dd} is a hydrogen atom, or a monovalent hydrocarbon group having a carbon number of 1 to 10; and s is an integer of 1 to 3.

When the structural unit (VI) has the alkali soluble group (x), R^{F} is a hydrogen atom; A¹ is an oxygen atom, —COO—* or —SO₂O—*; * refers to a bond to R^{F}; W¹ is a single bond, a hydrocarbon group having a carbon number of 1 to 20, or a divalent fluorinated hydrocarbon group. When A¹ is an oxygen atom, W¹ is a fluorinated hydrocarbon group having a fluorine atom or a fluoroalkyl group on the carbon atom connecting to A¹. R^{E} is a single bond, or a divalent organic group having a carbon number of 1 to 20. When s is 2 or 3, a plurality of R^{E}, W¹, A¹ and R^{F} may be each identical or different. The affinity of the high fluorine-content polymer into the alkaline developing solution can be improved by including the structural unit (VI) having the alkali soluble group (x), and thereby prevent from generating the development defect. As the structural unit (VI) having the alkali soluble group (x), particularly preferred is a structural unit in which A¹ is an oxygen atom and W¹ is a 1,1,1,3,3,3-hexafluoro-2,2-methanediyl group.

When the structural unit (VI) has the alkali-dissociable group (y), R^{E} is a monovalent organic group having carbon number of 1 to 30; A¹ is an oxygen atom, —NR^{aa}—, —COO—*, —OCO—*, or —SO₂O—*; R^{aa} is a hydrogen atom, or a monovalent hydrocarbon group having a carbon number of 1 to 10; * refers to a bond to R^{E}; W¹ is a single bond, or a divalent fluorinated hydrocarbon group having a carbon number of 1 to 20; R^{E} is a single bond, or a divalent organic group having a carbon number of 1 to 20. When A¹ is —COO—*, —OCO—*, or —SO₂O—*, W¹ or R^{F} has a fluorine atom on the carbon atom connecting to A¹ or on the carbon atom adjacent to the carbon atom. When A¹ is an oxygen atom, W¹ and R^{E} are a single bond; R^{D} is a structure in which a carbonyl group is connected at the terminal on R^{E} side of the hydrocarbon group having a carbon number of 1 to 20; and R^{F} is an organic group having a fluorine atom. When s is 2 or 3, a plurality of R^{E}, W¹, A¹ and R^{F} may be each identical or different. The surface of the resist film is changed from hydrophobic to hydrophilic in the alkaline developing step by including the structural unit (VI) having the alkali-dissociable group (y). As a result, the affinity of the high fluorine-content polymer into the alkaline developing solution can be significantly improved, and thereby prevent from generating the development defect more efficiently. As the structural unit (VI) having the alkali-dissociable group (y), particularly preferred is a structural unit in which A¹ is —COO—*, and R^{F} or W¹, or both is/are a fluorine atom.

In terms of the copolymerizability of monomers resulting in the structural unit (VI), R^{C} is preferably a hydrogen atom or a methyl group, and more preferably a methyl group.

When the high fluorine-content polymer has the structural unit (VI), the lower limit of the content of the structural unit (VI) is preferably 40 mol %, more preferably 50 mol %, even more preferably 55 mol % with respect to the total amount of all the structural units constituting the high fluorine-content polymer. The upper limit of the content is preferably 95 mol %, more preferably 90 mol %, even more preferably 85 mol %. When the content of the structural unit (VI) is set to fall within the above range, water repellency of a resist film during immersion exposure can further be improved, and the occurrence of development defects can be suppressed.

### [Other Structural Unit]

A high fluorine-content polymer may contain a structural unit having an alicyclic structure represented by the above formula (6) as a structural unit other than the structural units listed above.

When the high fluorine-content polymer contains the structural unit having an alicyclic structure, the content ratio of the structural unit having an alicyclic structure is preferably 10 mol %, more preferably 20 mol %, and still more preferably 30 mol % with respect to all structural units constituting the high fluorine-content polymer. The upper limit of the content ratio is preferably 60 mol %, more preferably 50 mol %, and still more preferably 45 mol %.

The lower limit of the Mw of the high fluorine-content polymer is preferably 2,000, more preferably 3,000, still more preferably 4,000, and particularly preferably 5,000. The upper limit of the Mw is preferably 30,000, more preferably 20,000, still more preferably 10,000, particularly preferably 8,000.

The lower limit of the Mw/Mn of the high fluorine-content polymer is typically 1, and more preferably 1.1. The upper limit of the Mw/Mn is typically 5, preferably 3, more preferably 2.

When the radiation-sensitive composition contains a high fluorine-content polymer, the lower limit of the content of the high fluorine-content polymer is preferably 0.5 part by mass, more preferably 1 part by mass, further preferably 2 part by mass based on 100 parts by mass of total base polymers. The upper limit of the content is preferably 15 parts by mass, more preferably 10 parts by mass, further preferably 5 parts by mass.

When the content of the high fluorine-content polymer is set to fall within the above range, the high fluorine-content polymer can more effectively be localized in the surface layer of a resist film, which as a result makes it possible to further enhance the water repellency of the surface of the resist film during liquid immersion lithography, and control the surface modification of resist films and the distribution of composition within the film during EUV exposure. The radiation-sensitive composition may contain one kind of high fluorine-content polymer or two or more kinds of high fluorine-content polymers.

### (Method for Synthesizing High Fluorine-Content Polymer)

The high fluorine-content polymer can be synthesized by a method similar to the above-described method for synthesizing a base polymer.

### (Radiation-Sensitive Acid Generator)

The radiation-sensitive composition of the present embodiment preferably further contains a radiation-sensitive acid generator that generates an acid having a pka smaller than that of the acid generated from the onium salt (1) by irradiation (exposure), that is, a relatively strong acid. When the polymer contains the structural unit (I) having an acid-dissociable group, the acid generated from the radiation-sensitive acid generator by exposure can dissociate the acid-dissociable group of the structural unit (I) to generate a carboxy group or the like. This function is different from the function of the onium salt (1) that suppresses the diffusion of the acid generated from the radiation-sensitive acid generator in the non-exposed part without substantially dissociating the acid-dissociable group or the like of the structural unit (I) or the like of the polymer under the pattern formation condition using the radiation-sensitive composition. Each function of the onium salt (1) and the radiation-sensitive acid generator depends on energy required for the dissociation of the acid-dissociable group of the structural unit (I) or the like of the polymer, the acidity of the acid generated from the radiation-sensitive acid generator, and the like. The containing mode of the radiation-sensitive acid generator in the radiation-sensitive composition may be a mode in which the radiation-sensitive acid generator is present alone as a compound (released from a polymer), a mode in which the radiation-sensitive acid generator is incorporated as a part of a polymer, or both of these forms, but a mode in which the radiation-sensitive acid generator is present alone as a compound is preferable.

When the radiation-sensitive composition contains the radiation-sensitive acid generator, the polarity of the polymer in the exposed part increases, whereby the polymer in the exposed part is soluble in the developer in the case of alkaline aqueous solution development, and is poorly soluble in the developer in the case of organic solvent development.

Examples of the radiation-sensitive acid generator include an onium salt (excluding the onium salt (1)), a sulfonimide compound, a halogen-containing compound, and a diazoketone compound. Examples of the onium salt include a sulfonium salt, a tetrahydrothiophenium salt, an iodonium salt, a phosphonium salt, a diazonium salt, and a pyridinium salt. Among them, a sulfonium salt and an iodonium salt are preferable.

Examples of the acid generated during exposure include acids that generate sulfonic acid during exposure. Examples of such an acid include a compound in which the carbon atom adjacent to the sulfo group is substituted with one or more fluorine atoms or fluorinated hydrocarbon groups. Among them, as the radiation-sensitive acid generator, a radiation-sensitive acid generator having a cyclic structure is particularly preferable.

These radiation-sensitive acid generators may be used alone or in combination of two or more thereof. The lower limit of the content of the radiation-sensitive acid generator (the total content in the case of a plurality of radiation-sensitive acid generators) is preferably 2 parts by mass and more preferably 5 parts by mass with respect to 100 parts by mass of the base polymer. The upper limit of the content is preferably 60 parts by mass, more preferably 50 parts by mass, and still more preferably 45 parts by mass, based on 100 parts by mass of the base polymer. This makes it possible to exert excellent various resist performances when having a resist pattern formed thereon.

### <Solvent>

The radiation-sensitive composition according to the present embodiment contains a solvent. The solvent is not particularly limited as long as it can dissolve or disperse at least the polymer, the radiation-sensitive acid generator, and an additive or the like contained if necessary.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:
a monoalcohol-based solvent having a carbon number of 1 to 18, including iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
a polyhydric alcohol having a carbon number of 2 to 18, including ethylene glycol, 1,2-propylene glycol, 2-methyl-2,4-pentanediol, 2,5-hexanediol, diethylene glycol, dipropylene glycol, triethylene glycol, and tripropylene glycol; and
a partially etherized polyhydric alcohol-based solvent in which a part of hydroxy groups in the polyhydric alcohol-based solvent is etherized.

In the present embodiment, the alcohol-based solvents also include alcohol acid esters such as methyl lactate, ethyl lactate, propyl lactate, butyl lactate, methyl 2-hydroxyisobutyrate, i-propyl 2-hydroxyisobutyrate, i-butyl 2-hydroxyisobutyrate, and n-butyl 2-hydroxyisobutyrate.

Examples of the ether-based solvent include:
a dialkyl ether-based solvent, including diethyl ether, dipropyl ether, and dibutyl ether;
a cyclic ether-based solvent, including tetrahydrofuran and tetrahydropyran;
an ether-based solvent having an aromatic ring, including diphenylether and anisole (methyl phenyl ether); and
an etherized polyhydric alcohol-based solvent in which a hydroxy group in the polyhydric alcohol-based solvent is etherized.

Examples of the ketone-based solvent include:
a chain ketone-based solvent, including acetone, butanone, and methyl-iso-butyl ketone;
a cyclic ketone-based solvent, including cyclopentanone, cyclohexanone, and methylcyclohexanone; and
2,4-pentanedione, acetonylacetone, and acetophenone.

Examples of the amide-based solvent include:
a cyclic amide-based solvent, including N,N′-dimethyl imidazolidinone and N-methylpyrrolidone; and
a chain amide-based solvent, including N-methylformamide, N, N-dimethylformamide, N, N-diethylformamide, acetamide, N-methylacetamide, N, N-dimethylacetamide, and N-methylpropionamide.

Examples of the ester-based solvent include:
a monocarboxylate ester-based solvent, including n-butyl acetate and ethyl lactate;
a partially etherized polyhydric alcohol acetate-based solvent, including diethylene glycol mono-n-butyl ether acetate, propylene glycol monomethyl ether acetate, and dipropylene glycol monomethyl ether acetate;
a lactone-based solvent, including y-butyrolactone and valerolactone;
a carbonate-based solvent, including diethyl carbonate, ethylene carbonate, and propylene carbonate; and
a polyhydric carboxylic acid diester-based solvent, including propylene glycol diacetate, methoxy triglycol acetate, diethyl oxalate, ethyl acetoacetate, ethyl lactate, and diethyl phthalate.

Examples of the hydrocarbon-based solvent include:
an aliphatic hydrocarbon-based solvent, including n-hexane, cyclohexane, and methylcyclohexane;
an aromatic hydrocarbon-based solvent, including benzene, toluene, di-iso-propylbenzene, and n-amylnaphthalene.

Among these, an alcohol-based solvent and an ester-based solvent are preferable, a polyhydric alcohol partial ether-base solvent, a polyhydric alcohol partial ether acetate-based solvent, a lactone-based solvent, and a monocarboxylic acid ester-based solvent are more preferable, and propylene glycol monomethyl ether, ethyl lactate, propylene glycol monomethyl ether acetate, and γ-butyrolactone are still more preferable. The radiation-sensitive composition may contain one solvent, or two or more solvents.

### <Other Optional Components>

The radiation-sensitive composition may contain other optional components other than the above-descried components. Examples of other optional components include a cross-linking agent, a localization enhancing agent, a surfactant, an alicyclic backbone-containing compound, and a sensitizer.

These other optional components may be used singly or in combination of two or more of them. The content of other optional components is usually 5 parts by mass or less based on 100 parts by mass of the polymer.

### <Method for Preparing Radiation-Sensitive Composition>

The radiation-sensitive composition can be prepared by, for example, mixing the onium salt (1), the polymer, and the solvent with the radiation-sensitive acid generator, the high fluorine-content polymer, and the like as necessary at a predetermined ratio. The radiation-sensitive composition is preferably filtered through, for example, a filter having a pore size of about 0.1 to 0.5 μm after mixing. The solid matter concentration of the radiation-sensitive composition is usually 0.1 mass % to 50 mass %, preferably 0.5 mass % to 30 mass %, and more preferably 1 mass % to 20 mass %.

### <Method for Forming Pattern>

A pattern forming method according to an embodiment of the present invention includes:
(1) applying the radiation-sensitive composition directly or indirectly on a substrate to form a resist film (hereinafter, also referred to as a “resist film forming step”);
(2) exposing the resist film (hereinafter, also referred to as an “exposure step”); and
(3) developing the exposed resist film (hereinafter, also referred to as a “developing step”).

The method for forming a pattern uses the above-described radiation-sensitive composition excellent in various resist performances, and therefore a high-quality resist pattern can be formed. Hereinbelow, each of the steps will be described.

### [Resist Film Forming Step]

In this step (the above mentioned step (1)), a resist film is formed with the radiation-sensitive composition. Examples of the substrate on which the resist film is formed include one traditionally known in the art, including a silicon wafer, silicon dioxide, and a wafer coated with aluminum. An organic or inorganic antireflection film may be formed on the substrate, as disclosed in JP-B-06-12452 and JP-A-59-93448. Examples of the applicating method include a rotary coating (spin coating), flow casting, and roll coating. After applicating, a prebake (PB) may be carried out in order to evaporate the solvent in the film, if needed. The temperature of PB is typically from 60° C. to 150° C., and preferably from 80° C. to 140° C. The duration of PB is typically from 5 seconds to 600 seconds, and preferably from 10 seconds to 300 seconds. The thickness of the resist film formed is preferably from 10 nm to 1,000 nm, and more preferably from 10 nm to 500 nm.

When the immersion exposure is carried out, irrespective of presence of a water repellent polymer additive such as the high fluorine-content polymer in the radiation-sensitive composition, the formed resist film may have a protective film for the immersion which is not soluble into the immersion liquid on the film in order to prevent a direct contact between the immersion liquid and the resist film. As the protective film for the immersion, a solvent-removable protective film that is removed with a solvent before the developing step (for example, see JP-A-2006-227632); or a developer-removable protective film that is removed during the development of the developing step (for example, see WO2005-069076 and WO2006-035790) may be used. In terms of the throughput, the developer-removable protective film is preferably used.

When the next step, the exposure step, is performed with radiation having a wavelength of 50 nm or less, it is preferable to use a polymer having the structural unit (I) and the structural unit (IV) as the base polymer in the composition.

### [Exposing Step]

In this step (the above mentioned step (2)), the resist film formed in the resist film forming step as the step (1) is exposed by irradiating with a radioactive ray through a photomask (optionally through an immersion medium such as water). Examples of the radioactive ray used for the exposure include visible ray, ultraviolet ray, far ultraviolet ray, extreme ultraviolet ray (EUV); an electromagnetic wave including X ray and y ray; an electron beam; and a charged particle radiation such as x ray. Among them, far ultraviolet ray, an electron beam, or EUV is preferred. ArF excimer laser light (wavelength is 193 nm), KrF excimer laser light (wavelength is 248 nm), an electron beam, or EUV is more preferred.

When the exposure is carried out by immersion exposure, examples of the immersion liquid include water and fluorine-based inert liquid. The immersion liquid is preferably a liquid which is transparent with respect to the exposing wavelength, and has a minimum temperature factor of the refractive index so that the distortion of the light image reflected on the film becomes minimum. However, when the exposing light source is ArF excimer laser light (wavelength is 193 nm), water is preferably used because of the ease of availability and ease of handling in addition to the above considerations. When water is used, a small proportion of an additive that decreases the surface tension of water and increases the surface activity may be added. Preferably, the additive cannot dissolve the resist film on the wafer and can neglect an influence on an optical coating at an under surface of a lens. The water used is preferably distilled water.

After the exposure, post exposure bake (PEB) is preferably carried out to promote the dissociation of the acid-dissociable group in the polymer by the acid generated from the radiation-sensitive acid generator with the exposure in the exposed part of the resist film. The difference of solubility into the developer between the exposed part and the non-exposed part is generated by the PEB. The temperature of PEB is typically from 50° C. to 180° C., and preferably from 80° C. to 130° C. The duration of PEB is typically from 5 seconds to 600 seconds, and preferably from 10 seconds to 300 seconds.

### [Developing Step]

In this step (the above mentioned step (3)), the resist film exposed in the exposing step as the step (2) is developed. By this step, the predetermined resist pattern can be formed. After the development, the resist pattern is washed with a rinse solution such as water or alcohol, and the dried, in general.

Examples of the developer used for the development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferred, and 2.38% by mass of aqueous TMAH solution is more preferred.

In the case of the development with organic solvent, examples of the solvent include an organic solvent, including a hydrocarbon-based solvent, an ether-based solvent, an ester-based solvent, a ketone-based solvent, and an alcohol-based solvent; and a solvent containing an organic solvent. Examples of the organic solvent include one, two or more solvents listed as the solvent for the radiation-sensitive composition. Among them, an ether-based solvent, an ester-based solvent or a ketone-based solvent is preferred. As the ether-based solvent, a glycol ether-based solvent is preferable, and ethylene glycol monomethyl ether and propylene glycol monomethyl ether are more preferable. The ester-based solvent is preferably an acetate ester-based solvent, and more preferably n-butyl acetate or amyl acetate. The ketone-based solvent is preferably a chain ketone, and more preferably 2-heptanone. The content of the organic solvent in the developer is preferably not less than 80% by mass, more preferably not less than 90% by mass, further preferably not less than 95% by mass, and particularly preferably not less than 998 by mass. Examples of the ingredient other than the organic solvent in the developer include water and silicone oil.

As described above, the developer may be either an alkaline developer or an organic solvent developer, but it is preferable that the developer contains an organic solvent and the obtained pattern is a negative pattern.

Examples of the developing method include a method of dipping the substrate in a tank filled with the developer for a given time (dip method); a method of developing by putting and leaving the developer on the surface of the substrate with the surface tension for a given time (paddle method); a method of spraying the developer on the surface of the substrate (spray method); and a method of injecting the developer while scanning an injection nozzle for the developer at a constant rate on the substrate rolling at a constant rate (dynamic dispense method).

### <Onium Salt (1)>

The onium salt according to still another embodiment of the present disclosure is represented by formula (1).

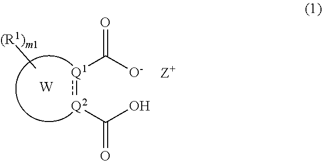

wherein,
Q¹ and Q² are each independently a carbon atom or a nitrogen atom, provided that at least one selected from the group consisting of Q¹ and Q² is a carbon atom,
W is a monocyclic or polycyclic non-aromatic ring structure of 3 to 40 ring members constituted together with Q¹ and Q² in the formula, and
formula between Q¹ and Q² in the formula represents a single bond or a double bond, [symbol]
R¹ is a monovalent organic group having 1 to 20 carbon atoms, a nitro group, a hydroxy group, an amino group, a thiol group, a cyano group, a carboxy group, or halogen atom, when there are a plurality of R¹'s, the plurality of R¹'s are the same or different from each other,
m₁ is an integer of 0 to 4, and
Z⁺ is a monovalent onium cation.

As the onium salt represented by the formula (1) according to the present embodiment, the onium salt (1) contained in the radiation-sensitive composition can be suitably used.

### EXAMPLES

Hereinafter, the present invention will be specifically described with reference to Examples, but the present invention is not limited to these Examples. Methods for measuring various physical property values are shown below.

### [Weight Average Molecular Weight (Mw) and Number Average Molecular Weight (Mn)]

The Mw and Mn of the polymer were measured under the conditions described above. The polydispersity (Mw/Mn) was calculated from the measurement results of Mw and Mn.

### [¹³C-NMR Analysis]

¹³C-NMR analysis of the polymer was performed using a nuclear magnetic resonance apparatus (“JNM-Delta 400” manufactured by JEOL Ltd.).

### <Synthesis of Polymer and High Fluorine-Content Polymer>

The monomers used in the synthesis of each polymer and high fluorine-content polymer in Examples and Comparative Examples are shown below. In the following synthesis examples, unless otherwise specified, parts by mass means a value when the total mass of monomers used is 100 parts by mass, and mol % means a value when the total number of moles of monomers used is 100 mol %.

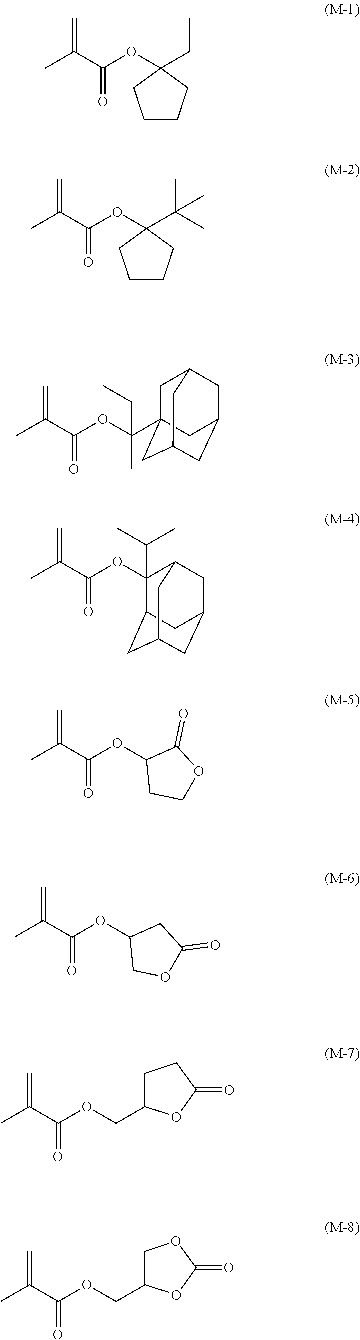

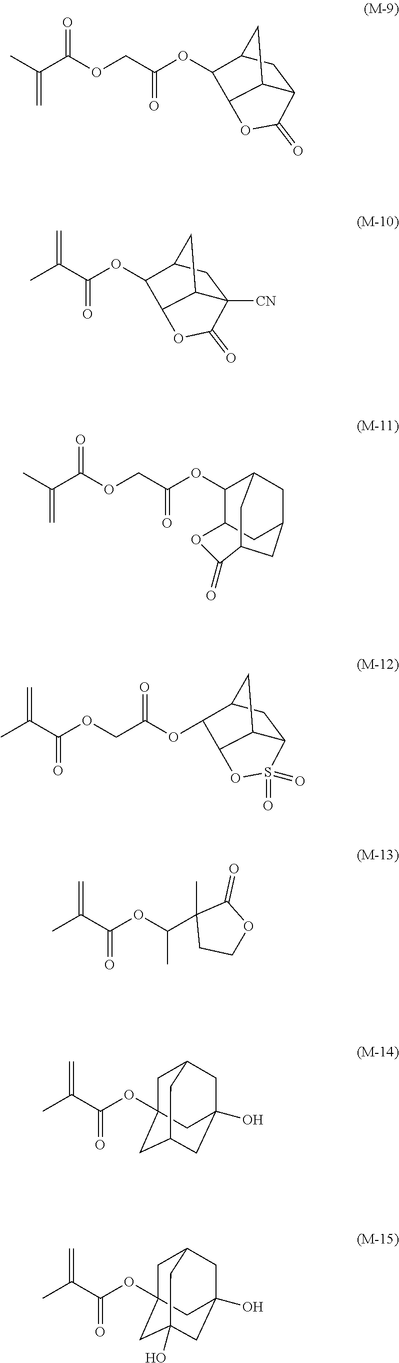

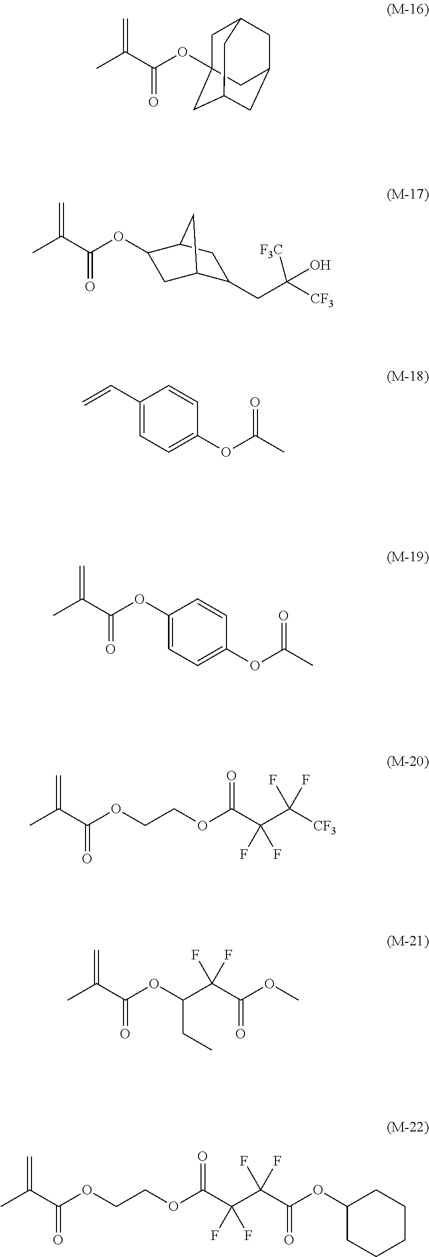

### Synthesis Example 1

### (Synthesis of Polymer (A-1))

A monomer (M-1), a monomer (M-4), a monomer (M-5), a monomer (M-11), and a monomer (M-14) were dissolved at a molar ratio of 40/10/20/20/10 (mol %) in 2-butanone (200 parts by mass), and AIBN (azobisisobutyronitrile) (3 mol % based on 100 molo in total of the monomers used) was added thereto as an initiator to prepare a monomer solution. A reaction vessel was charged with 2-butanone (100 parts by mass) and purged with nitrogen for 30 minutes, and inside of the reaction vessel was adjusted to 80° C. Then, the monomer solution was added dropwise thereto over 3 hours with stirring. The polymerization reaction was performed for 6 hours with the start of dropwise addition as the initiation time of the polymerization reaction. After completion of the polymerization reaction, the polymerization solution was cooled to 30° C. or lower by water cooling. The cooled polymerization solution was added to methanol (2,000 parts by mass), and the precipitated white powder was separated by filtration. The separated white powder was washed with methanol twice, then separated by filtration, and dried at 50° C. for 24 hours to obtain a white powdery polymer (A-1) (yield: 80%). The polymer (A-1) had a Mw of 9,100 and a Mw/Mn of 1.54. As a result of 13C-NMR analysis, the content ratios of the structural units derived from (M-1), (M-4), (M-5), (M-11), and (M-14) were 40.6 mol %, 9.7 mol %, 21.1 mol %, 20.5 molo, and 8.1 mol %, respectively.

### Synthesis Examples 2 to 11

### (Synthesis of Polymers (A-2) to (A-11))

Polymers (A-2) to (A-11) were synthesized in the same manner as in Synthesis Example 1 except that monomers of types and blending ratios shown in the following Table 1 were used. The content (mol %), yield (%), and physical property values (Mw and Mw/Mn) of each structural unit of the obtained polymers are shown together in the following Table 1. Incidentally, “-” in the following Table 1 indicates that the corresponding monomer was not used (the same applies to the following tables.).

TABLE 1

| | | Monomer that affords | | | Monomer that affords | | | Monomer that affords | | | | |
|---|---|---|---|---|---|---|---|---|---|---|---|---|
| | | structural unit (I) | | | structural unit (II) | | | structural unit (III) | | | | |
| | | | | Content | | | Content | | | Content | | |
| | | | | ratio of | | | ratio of | | | ratio of | | |
| | | | Blending | structural | | Blending | structural | | Blending | structural | | |
| | Polymer | | ratio | unit | | ratio | unit | | ratio | unit | | Mw/ |
| | [A] | Type | (mol %) | (mol %) | Type | (mol %) | (mol %) | Type | (mol %) | (mol %) | Mw | Mn |
| Synthesis | A-1 | M-1 | 40 | 40.6 | M-5 | 20 | 21.1 | M-14 | 10 | 8.1 | 9100 | 1.54 |
| Example 1 | | M-4 | 10 | 9.7 | M-11 | 20 | 20.5 | | | | | |
| Synthesis | A-2 | M-1 | 30 | 31.4 | M-6 | 60 | 60.6 | — | — | — | 9000 | 1.44 |
| Example 2 | | M-2 | 10 | 8.0 | | | | | | | | |
| Synthesis | A-3 | M-1 | 30 | 31.9 | M-5 | 60 | 59.2 | — | — | — | 8600 | 1.51 |
| Example 3 | | M-3 | 10 | 8.9 | | | | | | | | |
| Synthesis | A-4 | M-1 | 35 | 34.8 | M-12 | 45 | 46.4 | — | — | — | 7700 | 1.56 |
| Example 4 | | M-3 | 20 | 18.8 | | | | | | | | |
| Synthesis | A-5 | M-1 | 40 | 41.1 | M-10 | 45 | 46.8 | — | — | — | 7900 | 1.44 |
| Example 5 | | M-4 | 15 | 12.1 | | | | | | | | |
| Synthesis | A-6 | M-1 | 40 | 40.7 | M-11 | 45 | 46.1 | — | — | — | 8100 | 1.45 |
| Example 6 | | M-4 | 15 | 13.2 | | | | | | | | |
| Synthesis | A-7 | M-1 | 40 | 40.2 | M-10 | 30 | 29.6 | M-14 | 10 | 10.5 | 8000 | 1.57 |
| Example 7 | | | | | M-13 | 20 | 19.7 | | | | | |
| Synthesis | A-8 | M-1 | 40 | 40.2 | M-7 | 40 | 41.1 | M-15 | 20 | 18.7 | 8500 | 1.61 |
| Example 8 | | | | | | | | | | | | |
| Synthesis | A-9 | M-1 | 50 | 51.0 | M-8 | 50 | 49.0 | — | — | — | 7800 | 1.55 |
| Example 9 | | | | | | | | | | | | |
| Synthesis | A-10 | M-1 | 40 | 41.3 | M-9 | 60 | 58.7 | — | — | — | 8200 | 1.55 |
| Example 10 | | | | | | | | | | | | |
| Synthesis | A-11 | M-1 | 40 | 42.8 | M-6 | 60 | 57.2 | — | — | — | 8000 | 1.43 |
| Example 11 | | | | | | | | | | | | |

### Synthesis Example 12

### (Synthesis of Polymer (A-12))

The monomer (M-1) and the monomer (M-18) were dissolved in 1-methoxy-2-propanol (200 parts by mass) so as to have a molar ratio of 50/50 (mol %), and AIBN (5 mol %) was added as an initiator to prepare a monomer solution. A reaction vessel was charged with 1-methoxy-2-propanol (100 parts by mass) and purged with nitrogen for 30 minutes, and inside of the reaction vessel was adjusted to 80° C. Then, the monomer solution was added dropwise thereto over 3 hours with stirring. The polymerization reaction was performed for 6 hours with the start of dropwise addition as the initiation time of the polymerization reaction. After completion of the polymerization reaction, the polymerization solution was cooled to 30° C. or lower by water cooling. The cooled polymerization solution was added to hexane (2,000 parts by mass), and the precipitated white powder was separated by filtration. The separated white powder was washed twice with hexane, then separated by filtration, and dissolved in 1-methoxy-2-propanol (300 parts by mass). Subsequently, methanol (500 parts by mass), triethylamine (50 parts by mass), and ultrapure water (10 parts by mass) were added, and a hydrolysis reaction was performed at 70° C. for 6 hours with stirring. After completion of the reaction, the remaining solvent was distilled off, and the obtained solid was dissolved in acetone (100 parts by mass). The solution was added dropwise to water (500 parts by mass) to solidify the polymer. The resulting solid was separated by filtration and dried at 50° C. for 13 hours to obtain a white powdery polymer (A-12) (yield: 79%). The polymer (A-12) had a Mw of 5,200 and a Mw/Mn of 1.60. As a result of 13C-NMR analysis, the contents of the structural units derived from (M-1) and (M-18) were 51.3 mol % and 48.7 mol %, respectively.

### Synthesis Examples 13 to 15

### (Synthesis of Polymers (A-13) to (A-15))

Polymers (A-13) to (A-15) were synthesized in the same manner as in Synthesis Example 12 except that monomers of types and blending ratios shown in the following Table 2 were used. The content (mol %), and physical property values (Mw and Mw/Mn) of each structural unit of the obtained polymers are also shown in the following Table 2.

TABLE 2

| | | Monomer that affords | | | Monomer that affords | | | Monomer that affords | | | | |
|---|---|---|---|---|---|---|---|---|---|---|---|---|
| | | structural unit (I) | | | structural unit (II) | | | structural unit (III) | | | | |
| | | | | Content | | | Content | | | Content | | |
| | | | | ratio of | | | ratio of | | | ratio of | | |
| | | | Blending | structural | | Blending | structural | | Blending | structural | | |
| | Polymer | | ratio | unit | | ratio | unit | | ratio | unit | | Mw/ |
| | [A] | Type | (mol %) | (mol %) | Type | (mol %) | (mol %) | Type | (mol %) | (mol %) | Mw | Mn |
| Synthesis | A-12 | M-1 | 50 | 51.3 | — | — | — | M-18 | 50 | 48.7 | 5200 | 1.60 |
| Example 12 | | | | | | | | | | | | |
| Synthesis | A-13 | M-3 | 50 | 47.9 | M-14 | 10 | 10.3 | M-19 | 40 | 41.8 | 5500 | 1.53 |
| Example 13 | | | | | | | | | | | | |
| Synthesis | A-14 | M-2 | 50 | 48.1 | M-17 | 20 | 21.3 | M-18 | 30 | 30.6 | 5100 | 1.59 |
| Example 14 | | | | | | | | | | | | |
| Synthesis | A-15 | M-1 | 55 | 55.7 | M-17 | 15 | 15.1 | M-19 | 30 | 29.2 | 6100 | 1.50 |
| Example 15 | | | | | | | | | | | | |

### Synthesis Example 16

### (Synthesis of High Fluorine-Content Polymer (E-1))

The monomer (M-1), monomer (M-14) and the monomer (M-20) were dissolved in 2-butanone (200 parts by mass) so as to have a molar ratio of 20/10/70 (mol %), and AIBN (4 mol %) was added as an initiator to prepare a monomer solution. A reaction vessel was charged with 2-butanone (100 parts by mass) and purged with nitrogen for 30 minutes, and inside of the reaction vessel was adjusted to 80° C. Then, the monomer solution was added dropwise thereto over 3 hours with stirring. The polymerization reaction was performed for 6 hours with the start of dropwise addition as the initiation time of the polymerization reaction. After completion of the polymerization reaction, the polymerization solution was cooled to 30° C. or lower by water cooling. The operation of replacing the solvent with acetonitrile (400 parts by mass), then adding hexane (100 parts by mass), stirring the mixture, and recovering the acetonitrile layer was repeated three times. The solvent was replaced with propylene glycol monomethyl ether acetate to obtain a solution of a high fluorine-content polymer (E-1) (yield: 72%). The high fluorine-content polymer (E-1) had a Mw of 6, 500 and a Mw/Mn of 1.62. As a result of 13C-NMR analysis, the content ratios of the structural units derived from (M-1), (M-14), and (M-20) were 20.1 mol %, 9.6 mol %, and 70.3 mol %, respectively.

### Synthesis Examples 17 to 20

### (Synthesis of High Fluorine-Content Polymers (E-2) to (E-5))

High fluorine-content polymers (E-2) to (E-5) were synthesized in the same manner as in Synthesis Example 16 except that monomers of the types and blending ratios shown in the following Table 3 were used. The content (mol %), and physical property values (Mw and Mw/Mn) of each structural unit of the obtained high fluorine-content polymers are shown in the following Table 3.

TABLE 3

| | | Monomer that affords | | | Monomer that affords | | | Monomer that affords | | | Monomer that affords | | | | |
|---|---|---|---|---|---|---|---|---|---|---|---|---|---|---|---|
| | | structural unit (V) or (VI) | | | structural unit (I) | | | structural unit (II) | | | other structural unit | | | | |
| | | | | Content | | | Content | | | Content | | | Content | | |
| | High | | | ratio of | | | ratio of | | | ratio of | | | ratio of | | |
| | fluorine- | | Blend- | struc- | | Blend- | struc- | | Blend- | struc- | | Blend- | struc- | | |
| | content | | ing | tural | | ing | tural | | ing | tural | | ing | tural | | |
| | polymer | | ratio | unit | | ratio | unit | | ratio | unit | | ratio | unit | | Mw/ |
| | [E] | Type | (mol %) | (mol %) | Type | (mol %) | (mol %) | Type | (mol %) | (mol %) | Type | (mol %) | (mol %) | Mw | Mn |
| Synthesis | E-1 | M-20 | 70 | 70.3 | M-1 | 20 | 20.1 | M-14 | 10 | 9.6 | — | — | — | 6500 | 1.62 |
| Example 16 | | | | | | | | | | | | | | | |
| Synthesis | E-2 | M-21 | 80 | 81.9 | M-1 | 20 | 18.1 | — | — | — | — | — | — | 7200 | 1.77 |
| Example 17 | | | | | | | | | | | | | | | |
| Synthesis | E-3 | M-22 | 60 | 62.3 | — | — | — | — | — | — | M-16 | 40 | 37.7 | 6300 | 1.82 |
| Example 18 | | | | | | | | | | | | | | | |
| Synthesis | E-4 | M-22 | 60 | 60.3 | M-4 | 20 | 18.7 | M-14 | 20 | 21.0 | — | — | — | 7000 | 1.84 |
| Example 19 | | | | | | | | | | | | | | | |
| Synthesis | E-5 | M-20 | 60 | 59.2 | M-2 | 10 | 10.3 | M-17 | 30 | 30.5 | — | — | — | 6100 | 1.86 |
| Example 20 | | | | | | | | | | | | | | | |

### Synthesis of Acid Diffusion Controlling Agent C

### Example C1

### (Synthesis of Compound (C-1))

A compound (C-1) was synthesized according to synthesis scheme below.

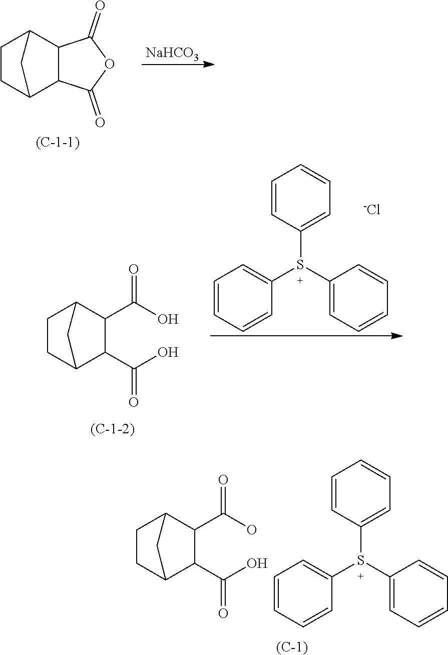

To a reaction vessel, 20.0 mmol of the compound (C-1-1) and 50 g of a saturated aqueous solution of sodium bicarbonate were added, and the mixture was stirred at room temperature for 24 hours. 1 M hydrochloric acid was added to stop the reaction, followed by addition of ethyl acetate and extraction, and then the organic layer was separated. After drying over sodium sulfate, a solvent was distilled off to obtain a dicarboxylic acid form (C-1-2) in a good yield.

20.0 mmol of sodium bicarbonate and 20.0 mmol of triphenylsulfonium chloride were added to the dicarboxylic acid form, and a mixed liquid of water and dichloromethane (1:3 (mass ratio)) was added to form a 0.5 M solution. The mixture was vigorously stirred at room temperature for 3 hours, and then extracted by adding dichloromethane, to separate an organic layer. The obtained organic layer was dried over sodium sulfate, and then the solvent was distilled off to obtain a compound (C-1) represented by the formula (C-1) in a good yield.

### Examples C2 to C7

### (Synthesis of Compounds (C-2) to (C-7))

Onium salts represented by formulas (C-2) to (C-7) were synthesized in the same manner as in Example C1 except that the raw materials and the precursor were appropriately changed. 5

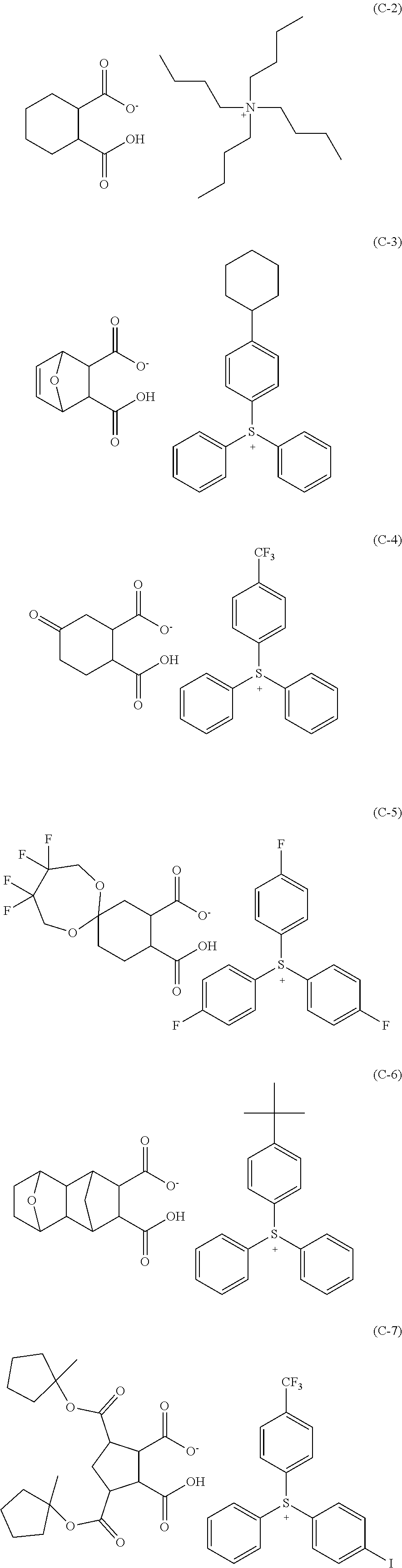

### Example C8

### (Synthesis of Compound (C-8))

A compound (C-8) was synthesized according to synthesis scheme below.

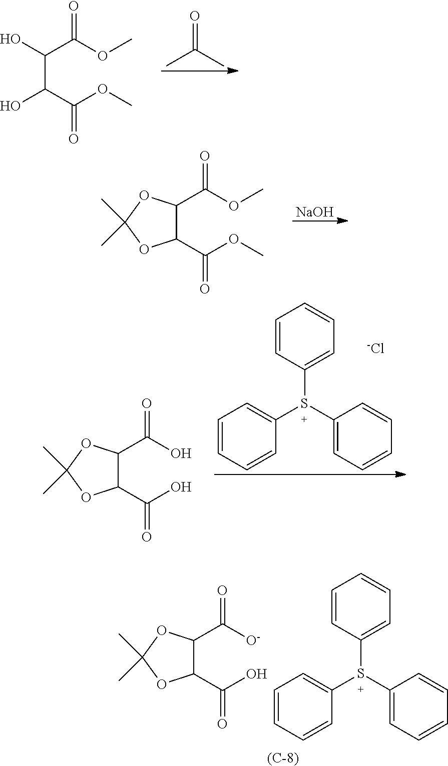

To a reaction vessel, 20.0 mmol of dimethyl tartrate, 20.0 mmol of acetone, 2.0 mmol of sulfuric acid, and 50 g of chloroform were added, and the mixture was stirred at 60° C. for 4 hours. Thereafter, a saturated aqueous solution of sodium bicarbonate was added to the reaction solution to terminate the reaction, and ethyl acetate was then added thereto to perform extraction, thereby separating an organic layer. The resulting organic layer was washed with a saturated aqueous solution of sodium chloride and then with water. After drying over sodium sulfate, a solvent was distilled off, and the residue was purified by column chromatography, affording an acetal form in a good yield.

To the acetal form, 50 g of a 1 M aqueous sodium hydroxide solution was added, and the mixture was stirred at room temperature for 4 hours. 1 M hydrochloric acid was added to stop the reaction, followed by addition of ethyl acetate and extraction, and then the organic layer was separated. After drying over sodium sulfate, a solvent was distilled off to obtain a dicarboxylic acid form in a good yield.

20.0 mmol of sodium bicarbonate and 20.0 mmol of triphenylsulfonium chloride were added to the dicarboxylic acid form, and a mixed liquid of water and dichloromethane (1:3 (mass ratio)) was added to form a 0.5 M solution. The mixture was vigorously stirred at room temperature for 3 hours, and then extracted by adding dichloromethane, to separate an organic layer. The obtained organic layer was dried over sodium sulfate, and then the solvent was distilled off to obtain a compound (C-8) represented by the formula (C-8) in a good yield.

### Examples C9 to C11

### (Synthesis of Compounds (C-9) to (C-11))

Onium salts represented by formulas (C-9) to (C-11) were synthesized in the same manner as in Example C8 except that the raw materials and the precursor were appropriately changed.

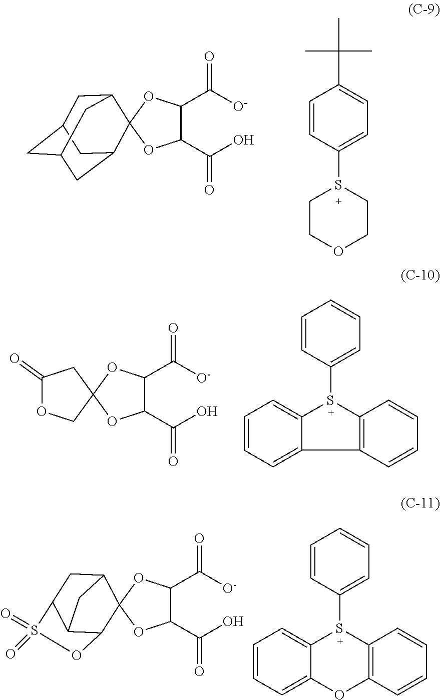

### Example C12

### (Synthesis of Compound (C-12))

A compound (C-12) was synthesized according to synthesis scheme below.

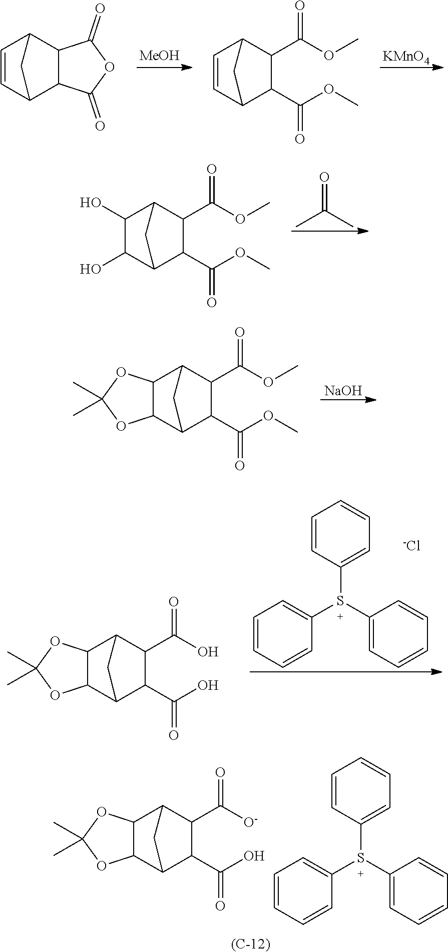

To a reaction vessel, 20.0 mmol of 5-norbornene-2,3-dicarboxylic anhydride, 20 g of methanol, and 20 g of 12 M hydrochloric acid were added, and the mixture was stirred at 65° C. for 4 hours. Thereafter, a saturated aqueous solution of sodium bicarbonate was added to the reaction solution to terminate the reaction, and ethyl acetate was then added thereto to perform extraction, thereby separating an organic layer. The resulting organic layer was washed with a saturated aqueous solution of sodium chloride and then with water. After drying over sodium sulfate, a solvent was distilled off, and purification was performed by column chromatography to obtain a diester form in a good yield.

To the diester form, 30.0 mmol of potassium permanganate and a mixed liquid of water and dichloromethane (1:1 (mass ratio)) were added to form a 0.5 M solution, and the solution was stirred at 55° C. for 10 hours. Impurities were removed by Celite filtration, followed by addition of ethyl acetate and extraction, and then the organic layer was separated. The resulting organic layer was washed with a saturated aqueous solution of sodium chloride and then with water. After drying over sodium sulfate, the solvent was distilled off, and the residue was purified by column chromatography, affording a diol form in a good yield.

To the diol form, 20.0 mmol of acetone, 2.0 mmol of sulfuric acid, and 50 g of chloroform were added, and the mixture was stirred at 80° C. for 10 hours. Thereafter, a saturated aqueous solution of sodium bicarbonate was added to the reaction solution to terminate the reaction, and ethyl acetate was then added thereto to perform extraction, thereby separating an organic layer. The resulting organic layer was washed with a saturated aqueous solution of sodium chloride and then with water. After drying over sodium sulfate, a solvent was distilled off, and the residue was purified by column chromatography, affording an acetal form in a good yield.

To the acetal form, 50 g of a 1 M aqueous sodium hydroxide solution was added, and the mixture was stirred at 50° C. for 5 hours. 1 M hydrochloric acid was added to stop the reaction, followed by addition of ethyl acetate and extraction, and then the organic layer was separated. After drying over sodium sulfate, a solvent was distilled off to obtain a dicarboxylic acid form in a good yield.

20.0 mmol of sodium bicarbonate and 20.0 mmol of triphenylsulfonium chloride were added to the dicarboxylic acid form, and a mixed liquid of water and dichloromethane (1:3 (mass ratio)) was added to form a 0.5 M solution. The mixture was vigorously stirred at room temperature for 3 hours, and then extracted by adding dichloromethane, to separate an organic layer. The obtained organic layer was dried over sodium sulfate, and then the solvent was distilled off to obtain a compound (C-12) represented by the formula (C-12) in a good yield.

### Examples C13 to C15

### (Synthesis of Compounds (C-13) to (C-15))

Onium salts represented by formulas (C-13) to (C-15) were synthesized in the same manner as in Example C12 except that the raw materials and the precursor were appropriately changed.

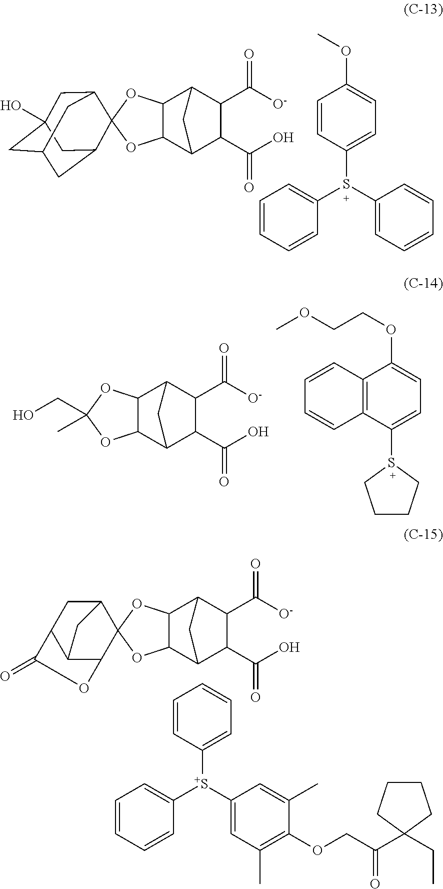

### Example C16

### (Synthesis of Compound (C-16))

A compound (C-16) was synthesized according to synthesis scheme below.

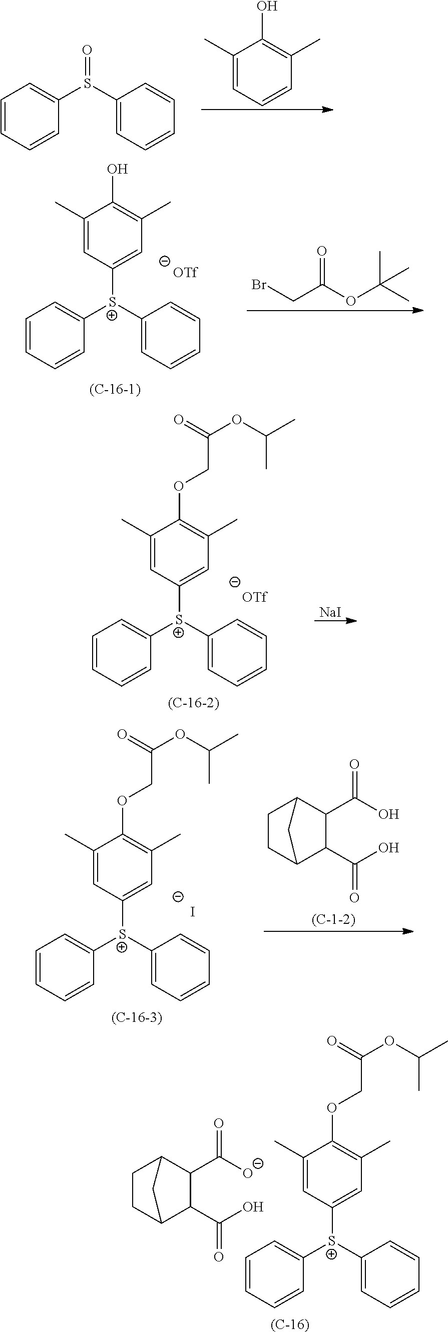

To a reaction vessel, 20.0 mmol of diphenyl sulfoxide, 40.0 mmol of 2,6-dimethylphenol, 30.0 mmol of trifluorosulfonic anhydride (Tf₂O), and 50 g of dichloromethane were added, and the mixture was stirred at 0° C. for 4 hours. Thereafter, a saturated aqueous solution of sodium bicarbonate was added to the reaction solution to terminate the reaction, and dichloromethane was then added thereto to perform extraction, thereby separating an organic layer. The resulting organic layer was washed with a saturated aqueous solution of sodium chloride and then with water. After the organic layer was dried over sodium sulfate, the solvent was distilled off, and the residue was purified by column chromatography, affording a compound (C-16-1) in a good yield.

To the compound (C-16-1), 20.0 mmol of potassium carbonate, 30.0 mmol of tert-butyl bromoacetate, and 50 g of dimethylformamide were added, and the mixture was stirred at room temperature for 4 hours. Thereafter, a saturated aqueous solution of ammonium chloride was added to the reaction solution to terminate the reaction, and dichloromethane was then added thereto to perform extraction, thereby separating an organic layer. The resulting organic layer was washed with a saturated aqueous solution of sodium chloride and then with water. After the organic layer was dried over sodium sulfate, the solvent was distilled off, and the residue was purified by column chromatography, affording a compound (C-16-2) in a good yield.

To the compound (C-16-2), 50 g of 1 M aqueous sodium iodide solution and 50 g of dichloromethane were added, and the mixture was stirred at 50° C. for 12 hours. Thereafter, dichloromethane was added to the reaction solution, followed by extraction, and then the organic layer was separated. The solvent in the obtained organic layer was distilled off to obtain a compound (C-16-3) in a good yield.

20.0 mmol of the compound (C-1-2), 20.0 mmol of sodium bicarbonate, 50 g of dichloromethane, and 50 g of water were added to the compound (C-16-3), and the mixture was stirred at room temperature for 4 hours. Dichloromethane was added to the reaction liquid, followed by extraction, and then the organic layer was separated. The obtained organic layer was dried over sodium sulfate, and then the solvent was distilled off to obtain a compound (C-16) represented by the formula (C-16) in a good yield.

### Examples C17 to C18

### (Synthesis of Compounds (C-17) to (C-18))

Onium salts represented by formulas (C-17) to (C-18) were synthesized in the same manner as in Example C16 except that the raw materials and the precursor were appropriately changed.

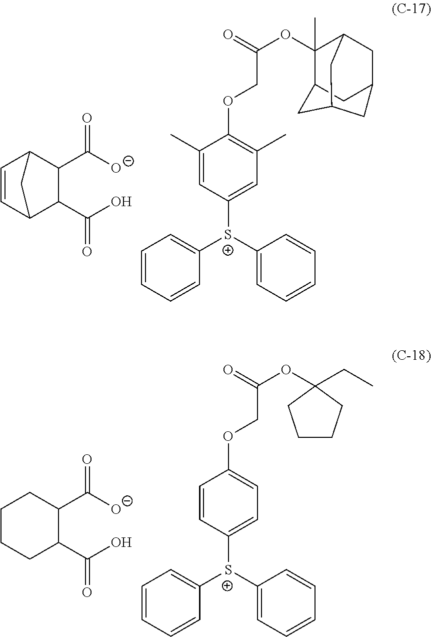 [SMILES: O=C([O-])C1C2C=CC(C2)C1C(=O)O ; Cc1cc([S+](c2ccccc2)c2ccccc2)cc(C)c1OCC(=O)OC1(C)C2CC3CC(C2)CC1C3 ; O=C([O-])C1CCCCC1C(=O)O ; CCC1(OC(=O)COc2ccc([S+](c3ccccc3)c3ccccc3)cc2)CCCC1]

[Onium Salts Other than Compounds (C-1) to (C-18)]

cc-1 to cc-8: Compounds represented by formulas (cc-1) to (cc-8) (hereinafter, the compounds represented by the formulas (cc-1) to (cc-8) may be described as “compound (cc-1)” to “compound (cc-8)”, respectively).

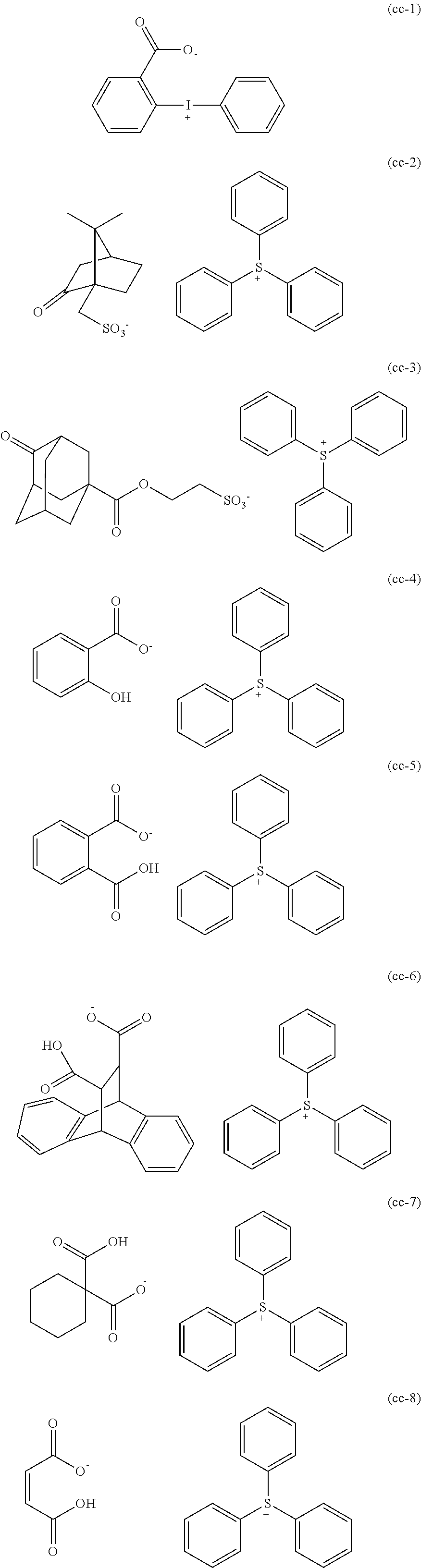

### [Radiation-Sensitive Acid Generator [B]]

B-1 to B-8: Compounds represented by formulas (B-1) to (B-8) (hereinafter, the compounds represented by the formulas (B-1) to (B-8) may be described as “compound (B-1)” to “compound (B-8)”, respectively).

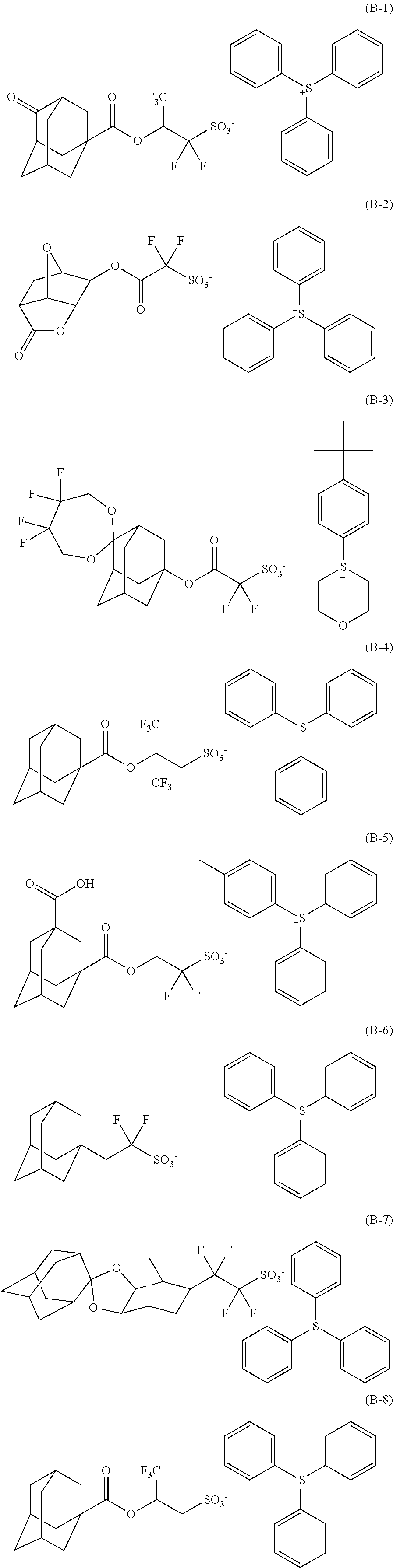

### [[D] Solvent]

D-1: Propylene glycol monomethyl ether acetate
D-2: Propylene glycol monomethyl ether
D-3: Y-Butyrolactone
D-4: Ethyl lactate

### [Preparation of Positive Radiation-Sensitive Composition for ArF Exposure]

### Example 1

100 parts by mass of (A-1) as the polymer [A], 12.0 parts by mass of (B-1) as the radiation-sensitive acid generator [B], 8.0 parts by mass of (C-1) as the acid diffusion controlling agent [C], 3.0 parts by mass (solid content) of (E-1) as the high fluorine-content polymer [E], and 3,400 parts by mass of a mixed solvent of (D-1)/(D-2)/(D-3) as the solvent [D] were mixed, and the mixture was filtered through a membrane filter having a pore size of 0.2 μm to prepare a radiation-sensitive composition (J-1).

### Examples 2 to 45 and 60 to 62 and Comparative Examples 1 to 8

Radiation-sensitive compositions (J-2) to (J-45), (J-60) to (J-62), and (CJ-1) to (CJ-8) were prepared in the same manner as in Example 1 except that the components of the types and contents shown in the following Table 4 were used.

TABLE 4

| | | | | Radiation-sensitive | | Acid diffusion | | High fluorine- | | | |
|---|---|---|---|---|---|---|---|---|---|---|---|
| | | Polymer [A] | | acid generator [B] | | controlling agent [C] | | content polymer [E] | | Solvent [D] | |
| | Radiation- | | Content | | Content | | Content | | Content | | Content |
| | sensitive | | (parts by | | (parts by | | (parts by | | (parts by | | (parts by |
| | composition | Type | mass) | Type | mass) | Type | mass) | Type | mass) | Type | mass) |
| Example 1 | J-1 | A-1 | 100 | B-1 | 12.0 | C-1 | 8.0 | E-1 | 3.0 | D-1/D-2/D-3 | 2240/960/200 |
| Example 2 | J-2 | A-1 | 100 | B-1 | 12.0 | C-2 | 8.0 | E-1 | 3.0 | D-1/D-2/D-3 | 2240/960/200 |
| Example 3 | J-3 | A-1 | 100 | B-1 | 12.0 | C-3 | 8.0 | E-1 | 3.0 | D-1/D-2/D-3 | 2240/960/200 |
| Example 4 | J-4 | A-1 | 100 | B-1 | 12.0 | C-4 | 8.0 | E-1 | 3.0 | D-1/D-2/D-3 | 2240/960/200 |
| Example 5 | J-5 | A-1 | 100 | B-1 | 12.0 | C-5 | 8.0 | E-1 | 3.0 | D-1/D-2/D-3 | 2240/960/200 |
| Example 6 | J-6 | A-1 | 100 | B-1 | 12.0 | C-6 | 8.0 | E-1 | 3.0 | D-1/D-2/D-3 | 2240/960/200 |
| Example 7 | J-7 | A-1 | 100 | B-1 | 12.0 | C-7 | 8.0 | E-1 | 3.0 | D-1/D-2/D-3 | 2240/960/200 |
| Example 8 | J-8 | A-1 | 100 | B-1 | 12.0 | C-8 | 8.0 | E-1 | 3.0 | D-1/D-2/D-3 | 2240/960/200 |
| Example 9 | J-9 | A-1 | 100 | B-1 | 12.0 | C-9 | 8.0 | E-1 | 3.0 | D-1/D-2/D-3 | 2240/960/200 |
| Example 10 | J-10 | A-1 | 100 | B-1 | 12.0 | C-10 | 8.0 | E-1 | 3.0 | D-1/D-2/D-3 | 2240/960/200 |
| Example 11 | J-11 | A-1 | 100 | B-1 | 12.0 | C-11 | 8.0 | E-1 | 3.0 | D-1/D-2/D-3 | 2240/960/200 |
| Example 12 | J-12 | A-1 | 100 | B-1 | 12.0 | C-12 | 8.0 | E-1 | 3.0 | D-1/D-2/D-3 | 2240/960/200 |
| Example 13 | J-13 | A-1 | 100 | B-1 | 12.0 | C-13 | 8.0 | E-1 | 3.0 | D-1/D-2/D-3 | 2240/960/200 |
| Example 14 | J-14 | A-1 | 100 | B-1 | 12.0 | C-14 | 8.0 | E-1 | 3.0 | D-1/D-2/D-3 | 2240/960/200 |
| Example 15 | J-15 | A-1 | 100 | B-1 | 12.0 | C-15 | 8.0 | E-1 | 3.0 | D-1/D-2/D-3 | 2240/960/200 |
| Example 16 | J-16 | A-2 | 100 | B-1 | 12.0 | C-1 | 8.0 | E-1 | 3.0 | D-1/D-2/D-3 | 2240/960/200 |
| Example 17 | J-17 | A-3 | 100 | B-1 | 12.0 | C-1 | 8.0 | E-1 | 3.0 | D-1/D-2/D-3 | 2240/960/200 |
| Example 18 | J-18 | A-4 | 100 | B-1 | 12.0 | C-1 | 8.0 | E-1 | 3.0 | D-1/D-2/D-3 | 2240/960/200 |
| Example 19 | J-19 | A-5 | 100 | B-1 | 12.0 | C-1 | 8.0 | E-1 | 3.0 | D-1/D-2/D-3 | 2240/960/200 |
| Example 20 | J-20 | A-6 | 100 | B-1 | 12.0 | C-1 | 8.0 | E-1 | 3.0 | D-1/D-2/D-3 | 2240/960/200 |
| Example 21 | J-21 | A-7 | 100 | B-1 | 12.0 | C-1 | 8.0 | E-1 | 3.0 | D-1/D-2/D-3 | 2240/960/200 |
| Example 22 | J-22 | A-8 | 100 | B-1 | 12.0 | C-1 | 8.0 | E-1 | 3.0 | D-1/D-2/D-3 | 2240/960/200 |
| Example 23 | J-23 | A-9 | 100 | B-1 | 12.0 | C-1 | 8.0 | E-1 | 3.0 | D-1/D-2/D-3 | 2240/960/200 |
| Example 24 | J-24 | A-10 | 100 | B-1 | 12.0 | C-1 | 8.0 | E-1 | 3.0 | D-1/D-2/D-3 | 2240/960/200 |
| Example 25 | J-25 | A-11 | 100 | B-1 | 12.0 | C-1 | 8.0 | E-1 | 3.0 | D-1/D-2/D-3 | 2240/960/200 |
| Example 26 | J-26 | A-1 | 100 | B-2 | 12.0 | C-1 | 8.0 | E-1 | 3.0 | D-1/D-2/D-3 | 2240/960/200 |
| Example 27 | J-27 | A-1 | 100 | B-3 | 12.0 | C-1 | 8.0 | E-1 | 3.0 | D-1/D-2/D-3 | 2240/960/200 |
| Example 28 | J-28 | A-1 | 100 | B-4 | 12.0 | C-1 | 8.0 | E-1 | 3.0 | D-1/D-2/D-3 | 2240/960/200 |
| Example 29 | J-29 | A-1 | 100 | B-5 | 12.0 | C-1 | 8.0 | E-1 | 3.0 | D-1/D-2/D-3 | 2240/960/200 |
| Example 30 | J-30 | A-1 | 100 | B-6 | 12.0 | C-1 | 8.0 | E-1 | 3.0 | D-1/D-2/D-3 | 2240/960/200 |
| Example 31 | J-31 | A-1 | 100 | B-7 | 12.0 | C-1 | 8.0 | E-1 | 3.0 | D-1/D-2/D-3 | 2240/960/200 |
| Example 32 | J-32 | A-1 | 100 | B-8 | 12.0 | C-1 | 8.0 | E-1 | 3.0 | D-1/D-2/D-3 | 2240/960/200 |
| Example 33 | J-33 | A-1 | 100 | B-1 | 12.0 | C-1 | 8.0 | E-2 | 3.0 | D-1/D-2/D-3 | 2240/960/200 |
| Example 34 | J-34 | A-1 | 100 | B-1 | 12.0 | C-1 | 8.0 | E-3 | 3.0 | D-1/D-2/D-3 | 2240/960/200 |
| Example 35 | J-35 | A-1 | 100 | B-1 | 12.0 | C-1 | 8.0 | E-4 | 3.0 | D-1/D-2/D-3 | 2240/960/200 |
| Example 36 | J-36 | A-1 | 100 | B-1 | 12.0 | C-1 | 0.5 | E-1 | 3.0 | D-1/D-2/D-3 | 2240/960/200 |
| Example 37 | J-37 | A-1 | 100 | B-1 | 12.0 | C-1 | 4.0 | E-1 | 3.0 | D-1/D-2/D-3 | 2240/960/200 |
| Example 38 | J-38 | A-1 | 100 | B-1 | 12.0 | C-1 | 15.0 | E-1 | 3.0 | D-1/D-2/D-3 | 2240/960/200 |
| Example 39 | J-39 | A-1 | 100 | B-1 | 12.0 | C-1/C-2 | 4.0/4.0 | E-1 | 3.0 | D-1/D-2/D-3 | 2240/960/200 |
| Example 40 | J-40 | A-1 | 100 | B-1 | 12.0 | C-1/C-13 | 4.0/4.0 | E-1 | 3.0 | D-1/D-2/D-3 | 2240/960/200 |
| Example 41 | J-41 | A-1 | 100 | B-1 | 12.0 | C-1/cc-1 | 6.0/2.0 | E-1 | 3.0 | D-1/D-2/D-3 | 2240/960/200 |
| Example 42 | J-42 | A-1 | 100 | B-1 | 12.0 | C-2/cc-4 | 6.0/2.0 | E-1 | 3.0 | D-1/D-2/D-3 | 2240/960/200 |
| Example 43 | J-43 | A-1 | 100 | B-1/B-8 | 6.0/6.0 | C-1 | 8.0 | E-1 | 3.0 | D-1/D-2/D-3 | 2240/960/200 |
| Example 44 | J-44 | A-1 | 100 | B-3/B-4 | 6.0/6.0 | C-1 | 8.0 | E-1 | 3.0 | D-1/D-2/D-3 | 2240/960/200 |
| Example 45 | J-45 | A-1 | 100 | B-5/B-7 | 6.0/6.0 | C-1 | 8.0 | E-1 | 3.0 | D-1/D-2/D-3 | 2240/960/200 |
| Example 60 | J-60 | A-1 | 100 | B-1 | 12.0 | C-16 | 8.0 | E-1 | 3.0 | D-1/D-2/D-3 | 2240/960/200 |
| Example 61 | J-61 | A-1 | 100 | B-1 | 12.0 | C-17 | 8.0 | E-1 | 3.0 | D-1/D-2/D-3 | 2240/960/200 |
| Example 62 | J-62 | A-1 | 100 | B-1 | 12.0 | C-18 | 8.0 | E-1 | 3.0 | D-1/D-2/D-3 | 2240/960/200 |
| Comparative | CJ-1 | A-1 | 100 | B-1 | 12.0 | cc-1 | 8.0 | E-1 | 3.0 | D-1/D-2/D-3 | 2240/960/200 |
| Example 1 | | | | | | | | | | | |
| Comparative | CJ-2 | A-1 | 100 | B-1 | 12.0 | cc-2 | 8.0 | E-1 | 3.0 | D-1/D-2/D-3 | 2240/960/200 |
| Example 2 | | | | | | | | | | | |
| Comparative | CJ-3 | A-1 | 100 | B-1 | 12.0 | cc-3 | 8.0 | E-1 | 3.0 | D-1/D-2/D-3 | 2240/960/200 |
| Example 3 | | | | | | | | | | | |
| Comparative | CJ-4 | A-1 | 100 | B-1 | 12.0 | cc-4 | 8.0 | E-1 | 3.0 | D-1/D-2/D-3 | 2240/960/200 |
| Example 4 | | | | | | | | | | | |
| Comparative | CJ-5 | A-1 | 100 | B-1 | 12.0 | cc-5 | 8.0 | E-1 | 3.0 | D-1/D-2/D-3 | 2240/960/200 |
| Example 5 | | | | | | | | | | | |
| Comparative | CJ-6 | A-1 | 100 | B-1 | 12.0 | cc-6 | 8.0 | E-1 | 3.0 | D-1/D-2/D-3 | 2240/960/200 |
| Example 6 | | | | | | | | | | | |
| Comparative | CJ-7 | A-1 | 100 | B-1 | 12.0 | cc-7 | 8.0 | E-1 | 3.0 | D-1/D-2/D-3 | 2240/960/200 |
| Example 7 | | | | | | | | | | | |
| Comparative | CJ-8 | A-1 | 100 | B-1 | 12.0 | cc-8 | 8.0 | E-1 | 3.0 | D-1/D-2/D-3 | 2240/960/200 |
| Example 8 | | | | | | | | | | | |

### <Formation of Resist Pattern Using Positive Radiation-Sensitive Composition for ArF Exposure>

A composition for forming an underlayer antireflective film (“ARC66” manufactured by Brewer Science, Inc.) was applied onto a 12 inch silicon wafer using a spin coater (“CLEAN TRACK ACT12” manufactured by Tokyo Electron Limited), and then heated at 205° C. for 60 seconds to form an underlayer antireflective film having an average thickness of 100 nm. The positive radiation-sensitive composition for ArF exposure prepared above was applied onto the underlayer antireflective film using the spin coater, and subjected to PB (prebake) at 100° C. for 60 seconds. Thereafter, cooling was performed at 23° C. for 30 seconds to form a resist film having an average thickness of 110 nm. Next, the resist film was exposed through a 55 nm line- and -space mask pattern using an ArF excimer laser immersion exposure apparatus (“TWINSCAN XT-1900i” manufactured by ASML) with NA of 1.35 under an optical condition of Dipole (0=0.9/0.7). After the exposure, PEB (post exposure bake) was performed at 100° C. for 60 seconds. Thereafter, the resist film was subjected to alkaline development using a 2.38 mass % aqueous TMAH solution as an alkaline developer, and after the development, the resist film was washed with water and further dried to form a positive resist pattern (55 nm line- and -space pattern).

### <Evaluation>

The resist pattern formed using the positive radiation-sensitive composition for ArF exposure was evaluated on sensitivity, LWR performance, DOF performance, pattern rectangularity, EL performance, and pattern collapse resistance (minimum pre-collapse dimension) in accordance with the following methods. The results are shown in the following Table 5. It is to be noted that a scanning electron microscope (“CG-5000” manufactured by Hitachi High-Tech Corporation) was used for measurement of the resist pattern.

### [Sensitivity]

An exposure dose at which a 55 nm line- and -space pattern was formed in formation of a resist pattern using the positive radiation-sensitive composition for ArF exposure was defined as an optimum exposure dose, and this optimum exposure dose was defined as sensitivity (mJ/cm²). A case where the sensitivity was 30 mJ/cm² or less was evaluated as “good”, and a case where the sensitivity exceeded 30 mJ/cm² was evaluated as “poor”.

### [LWR Performance]

A 55 nm line- and -space resist pattern was formed by irradiation with the optimum exposure dose obtained in the evaluation of the sensitivity. The formed resist pattern was observed from above the pattern using the scanning electron microscope. The variation in line width was measured at 500 points in total, the value of 30 was obtained from the distribution of the measured values, and the value of 30 was defined as LWR (nm). A smaller value of LWR indicates smaller roughness of the line and better performance. A case where the LWR performance was 2.5 nm or less was evaluated as “good”, and a case where the LWR performance exceeded 2.5 nm was evaluated as “poor”.

### [DOF Performance]

In accordance with the method described in the “Measurement of sensitivity”, the range of depth of focus (DOF) in which the line width of the line- and -space pattern, which was a mask having dimensions such that the line width of the line- and -space pattern (1L1S) to be formed was 55 nm, formed as described above was 45 nm or more and 65 nm or less was measured. The DOF performance was evaluated to be “good” in a case of being 150 nm or more, and “poor” in a case of being less than 150 nm.

### [Pattern Rectangularity]

The 55 nm line- and -space resist pattern formed by irradiation with the optimum exposure dose obtained in the evaluation of the sensitivity was observed using the scanning electron microscope, and the sectional shape of the line- and -space pattern was evaluated. The rectangularity of the resist pattern was evaluated as “A” (extremely good) when the ratio of the length of the lower side to the length of the upper side in the sectional shape was 1 or more and 1.05 or less, “B” (good) when the ratio was more than 1.05 and 1.10 or less, and “C” (poor) when the ratio was more than 1.10.

### [EL Performance (Exposure Latitude)]

In the range of the exposure dose including the optimum exposure dose, resist patterns were formed by changing the exposure dose every 1 mJ/cm², and the line width of each resist pattern was measured using the scanning electron microscope. From the obtained relationship between the line width and the exposure dose, the exposure dose E (60) at which the line width was 60 nm and the exposure dose E (50) at which the line width was 50 nm were determined, and the exposure latitude (%) was calculated from the equation: exposure latitude (EL)=(E(50)−E(60))×100/(optimum exposure dose). The larger the value of the exposure latitude, the smaller the fluctuation in dimension among the patterns obtained when the exposure dose fluctuates, and the higher the yield at the time of manufacturing a device. When the value was 13% or more, the EL performance was evaluated as “good”, and when the value was less than 13%, the EL was evaluated as “poor”.

### [Pattern Collapse Resistance (Minimum Pre-Collapse Dimension)]

Exposure was performed through the 55 nm line- and -space mask pattern while changing the exposure dose by 1 mJ/cm². The line width of a pattern formed with an exposure dose smaller by 1 mJ/cm² than the exposure dose at which line collapse occurred was measured with the scanning electron microscope and was defined as the minimum pre-collapse dimension (nm). The smaller the value is, the higher the resistance to collapse of the pattern is.

TABLE 5

| | | | | | | | Minimum pre- |
|---|---|---|---|---|---|---|---|
| | Radiation- | | | | | | collapse |
| | sensitive | Sensitivity | LWR | DOF | Pattern | EL | dimension |
| | composition | (mJ/cm²) | (nm) | (nm) | Rectangularity | (%) | (nm) |
| Example 1 | J-1 | 25 | 1.9 | 200 | A | 16.9 | 35 |
| Example 2 | J-2 | 29 | 2.3 | 190 | A | 13.8 | 40 |
| Example 3 | J-3 | 27 | 2.0 | 200 | A | 17.8 | 38 |
| Example 4 | J-4 | 28 | 2.1 | 190 | A | 18.0 | 36 |
| Example 5 | J-5 | 26 | 2.0 | 200 | A | 17.8 | 36 |
| Example 6 | J-6 | 26 | 1.9 | 180 | A | 17.0 | 34 |
| Example 7 | J-7 | 27 | 1.8 | 200 | A | 20.3 | 34 |
| Example 8 | J-8 | 24 | 2.2 | 190 | A | 15.4 | 36 |
| Example 9 | J-9 | 26 | 2.1 | 180 | A | 19.6 | 35 |
| Example 10 | J-10 | 27 | 2.1 | 200 | A | 18.4 | 33 |
| Example 11 | J-11 | 25 | 2.0 | 190 | A | 18.7 | 38 |
| Example 12 | J-12 | 26 | 1.9 | 200 | A | 17.1 | 38 |
| Example 13 | J-13 | 27 | 1.8 | 180 | A | 19.0 | 37 |
| Example 14 | J-14 | 23 | 1.9 | 170 | A | 18.3 | 35 |
| Example 15 | J-15 | 25 | 2.0 | 180 | A | 18.7 | 35 |
| Example 16 | J-16 | 26 | 2.0 | 200 | A | 19.0 | 29 |
| Example 17 | J-17 | 27 | 2.1 | 180 | A | 17.1 | 30 |
| Example 18 | J-18 | 25 | 2.2 | 180 | A | 17.1 | 36 |
| Example 19 | J-19 | 24 | 2.2 | 170 | A | 15.1 | 36 |
| Example 20 | J-20 | 26 | 2.0 | 170 | A | 20.0 | 36 |
| Example 21 | J-21 | 24 | 1.9 | 190 | A | 15.8 | 32 |
| Example 22 | J-22 | 24 | 2.0 | 180 | A | 15.9 | 38 |
| Example 23 | J-23 | 23 | 1.9 | 190 | A | 16.8 | 37 |
| Example 24 | J-24 | 26 | 2.1 | 200 | A | 16.3 | 31 |
| Example 25 | J-25 | 23 | 2.0 | 190 | A | 18.4 | 34 |
| Example 26 | J-26 | 24 | 2.2 | 190 | A | 15.2 | 37 |
| Example 27 | J-27 | 26 | 2.1 | 180 | A | 20.6 | 32 |
| Example 28 | J-28 | 27 | 2.1 | 190 | A | 19.7 | 35 |
| Example 29 | J-29 | 24 | 2.0 | 180 | A | 15.6 | 34 |
| Example 30 | J-30 | 27 | 2.2 | 200 | A | 19.8 | 36 |
| Example 31 | J-31 | 27 | 2.0 | 190 | A | 17.2 | 31 |
| Example 32 | J-32 | 28 | 1.9 | 180 | A | 19.7 | 36 |
| Example 33 | J-33 | 25 | 1.9 | 200 | A | 16.8 | 35 |
| Example 34 | J-34 | 25 | 1.9 | 200 | A | 16.6 | 35 |
| Example 35 | J-35 | 25 | 2.0 | 200 | A | 17.0 | 35 |
| Example 36 | J-36 | 22 | 2.4 | 180 | A | 16.8 | 34 |
| Example 37 | J-37 | 24 | 2.2 | 170 | A | 16.5 | 36 |
| Example 38 | J-38 | 28 | 2.1 | 170 | A | 16.9 | 36 |
| Example 39 | J-39 | 27 | 2.1 | 180 | A | 14.0 | 40 |
| Example 40 | J-40 | 26 | 2.0 | 180 | A | 17.0 | 38 |
| Example 41 | J-41 | 28 | 2.3 | 160 | A | 19.6 | 33 |
| Example 42 | J-42 | 29 | 2.4 | 160 | A | 15.7 | 32 |
| Example 43 | J-43 | 26 | 2.0 | 180 | A | 20.1 | 34 |
| Example 44 | J-44 | 27 | 2.1 | 190 | A | 17.8 | 38 |
| Example 45 | J-45 | 27 | 1.9 | 180 | A | 17.5 | 33 |
| Example 60 | J-60 | 26 | 2.1 | 200 | A | 17.2 | 32 |
| Example 61 | J-61 | 25 | 2.0 | 180 | A | 18.9 | 35 |
| Example 62 | J-62 | 27 | 1.9 | 190 | A | 19.7 | 38 |
| Comparative | CJ-1 | 35 | 2.8 | 90 | C | 8.4 | 44 |
| Example 1 | | | | | | | |
| Comparative | CJ-2 | 32 | 3.0 | 80 | B | 5.4 | 48 |
| Example 2 | | | | | | | |
| Comparative | CJ-3 | 32 | 3.1 | 80 | B | 6.3 | 50 |
| Example 3 | | | | | | | |
| Comparative | CJ-4 | 32 | 2.9 | 70 | C | 9.3 | 45 |
| Example 4 | | | | | | | |
| Comparative | CJ-5 | 33 | 3.2 | 80 | C | 7.5 | 48 |
| Example 5 | | | | | | | |
| Comparative | CJ-6 | 36 | 3.6 | 60 | C | 5.6 | 47 |
| Example 6 | | | | | | | |
| Comparative | CJ-7 | 34 | 3.4 | 70 | C | 9.8 | 45 |
| Example 7 | | | | | | | |
| Comparative | CJ-8 | 35 | 3.2 | 70 | C | 7.9 | 48 |
| Example 8 | | | | | | | |

As is apparent from the results in Table 5, the radiation-sensitive compositions of Examples were good in sensitivity, LWR performance, DOF performance, pattern rectangularity, EL performance, and minimum pre-collapse dimension when used for ArF exposure, whereas the radiation-sensitive compositions of Comparative Examples were inferior in the characteristics to those of Examples. Therefore, when the radiation-sensitive compositions of Examples are used for ArF exposure, resist patterns having good LWR performance, DOF performance, and EL performance and excellent pattern shape and collapse resistance can be formed with high sensitivity.

### [Preparation of Positive Radiation-Sensitive Composition for Extreme Ultraviolet (EUV) Exposure]

### Example 46

100 parts by mass of (A-12) as the polymer [A], 40.0 parts by mass of (B-1) as the radiation-sensitive acid generator [B], 25.0 parts by mass of (C-1) as the acid diffusion controlling agent [C], 3.0 parts by mass (solid content) of (E-5) as the high fluorine-content polymer [E], and 6,550 parts by mass of a mixed solvent of (D-1)/(D-2)/(D-4) as the solvent [D] were mixed, and the mixture was filtered through a membrane filter having a pore size of 0.2 μm to prepare a radiation-sensitive composition (J-46).

### Examples 47 to 57 and Comparative Examples 9 to 13

Radiation-sensitive compositions (J-47) to (J-57) and (CJ-9) to (CJ-13) were prepared in the same manner as in Example 46 except that the components of the types and contents shown in the following Table 6 were used.

TABLE 6

| | | | | Radiation- | | | | | | | |
|---|---|---|---|---|---|---|---|---|---|---|---|
| | | | | sensitive acid | | Acid diffusion | | High fluorine- | | | |
| | | Polymer [A] | | generator [B] | | controlling agent [C] | | content polymer [E] | | Solvent [D] | |
| | Radiation- | | Content | | Content | | Content | | Content | | Content |
| | sensitive | | (parts by | | (parts by | | (parts by | | (parts by | | (parts by |
| | composition | Type | mass) | Type | mass) | Type | mass) | Type | mass) | Type | mass) |
| Example 46 | J-46 | A-12 | 100 | B-1 | 40.0 | C-1 | 25.0 | E-5 | 3.0 | D-1/D-2/D-4 | 4500/2000/50 |
| Example 47 | J-47 | A-12 | 100 | B-1 | 40.0 | C-2 | 25.0 | E-5 | 3.0 | D-1/D-2/D-4 | 4500/2000/50 |
| Example 48 | J-48 | A-12 | 100 | B-1 | 40.0 | C-7 | 25.0 | E-5 | 3.0 | D-1/D-2/D-4 | 4500/2000/50 |
| Example 49 | J-49 | A-12 | 100 | B-1 | 40.0 | C-8 | 25.0 | E-5 | 3.0 | D-1/D-2/D-4 | 4500/2000/50 |
| Example 50 | J-50 | A-12 | 100 | B-1 | 40.0 | C-12 | 25.0 | E-5 | 3.0 | D-1/D-2/D-4 | 4500/2000/50 |
| Example 51 | J-51 | A-12 | 100 | B-1 | 40.0 | C-15 | 25.0 | E-5 | 3.0 | D-1/D-2/D-4 | 4500/2000/50 |
| Example 52 | J-52 | A-13 | 100 | B-1 | 40.0 | C-1 | 25.0 | E-5 | 3.0 | D-1/D-2/D-4 | 4500/2000/50 |
| Example 53 | J-53 | A-14 | 100 | B-1 | 40.0 | C-1 | 25.0 | E-5 | 3.0 | D-1/D-2/D-4 | 4500/2000/50 |
| Example 54 | J-54 | A-15 | 100 | B-1 | 40.0 | C-1 | 25.0 | E-5 | 3.0 | D-1/D-2/D-4 | 4500/2000/50 |
| Example 55 | J-55 | A-12 | 100 | B-3 | 40.0 | C-1 | 25.0 | E-5 | 3.0 | D-1/D-2/D-4 | 4500/2000/50 |
| Example 56 | J-56 | A-12 | 100 | B-7 | 40.0 | C-1 | 25.0 | E-5 | 3.0 | D-1/D-2/D-4 | 4500/2000/50 |
| Example 57 | J-57 | A-12 | 100 | B-2/ | 20.0/ | C-1 | 25.0 | E-5 | 3.0 | D-1/D-2/D-4 | 4500/2000/50 |
| | | | | B-5 | 20.0 | | | | | | |
| Comparative | CJ-9 | A-12 | 100 | B-1 | 40.0 | cc-1 | 25.0 | E-5 | 3.0 | D-1/D-2/D-4 | 4500/2000/50 |
| Example 9 | | | | | | | | | | | |
| Comparative | CJ-10 | A-12 | 100 | B-1 | 40.0 | cc-5 | 25.0 | E-5 | 3.0 | D-1/D-2/D-4 | 4500/2000/50 |
| Example 10 | | | | | | | | | | | |
| Comparative | CJ-11 | A-12 | 100 | B-1 | 40.0 | cc-6 | 25.0 | E-5 | 3.0 | D-1/D-2/D-4 | 4500/2000/50 |
| Example 11 | | | | | | | | | | | |
| Comparative | CJ-12 | A-12 | 100 | B-1 | 40.0 | cc-7 | 25.0 | E-5 | 3.0 | D-1/D-2/D-4 | 4500/2000/50 |
| Example 12 | | | | | | | | | | | |
| Comparative | CJ-13 | A-12 | 100 | B-1 | 40.0 | cc-8 | 25.0 | E-5 | 3.0 | D-1/D-2/D-4 | 4500/2000/50 |
| Example 13 | | | | | | | | | | | |

### <Formation of Resist Pattern Using Positive Radiation-Sensitive Composition for EUV Exposure>

A composition for forming an underlayer antireflective film (“ARC66” manufactured by Brewer Science, Inc.) was applied onto a 12 inch silicon wafer using a spin coater (“CLEAN TRACK ACT12” manufactured by Tokyo Electron Limited), and then heated at 205° C. for 60 seconds to form an underlayer antireflective film having an average thickness of 30 nm. The positive radiation-sensitive composition for EUV exposure prepared above was applied onto the underlayer antireflective film using the spin coater, and subjected to PB at 130° C. for 60 seconds. Thereafter, cooling was performed at 23° C. for 30 seconds to form a resist film having an average thickness of 40 nm. Subsequently, this resist film was exposed with an EUV exposure apparatus (“NXE3300” manufactured by ASML Holding N.V.) with an NA of 0.33 under an illumination condition of conventional illumination (s=0.89), and with a mask of imecDEFECT32FFR02. After the exposure, PEB was performed at 120° C. for 60 seconds. Thereafter, the resist film was subjected to alkaline development using a 2.38 mass % aqueous TMAH solution as an alkaline developer, and after the development, the resist film was washed with water and further dried to form a positive resist pattern (27 nm line- and -space pattern).

### <Evaluation>

The sensitivity and LWR performance of each of resist patterns formed using the positive radiation-sensitive compositions for EUV exposure were evaluated according to the following methods. The results are shown in the following Table 7. It is to be noted that a scanning electron microscope (“CG-5000” manufactured by Hitachi High-Tech Corporation) was used for measurement of the resist pattern.

### [Sensitivity]

In formation of the resist pattern using the positive radiation-sensitive composition for EUV exposure, an exposure dose at which a 27 nm line- and -space pattern was formed was defined as an optimum exposure dose, and this optimum exposure dose was defined as sensitivity (mJ/cm²). A case where the sensitivity was 50 mJ/cm² or less was evaluated as “good”, and a case where the sensitivity exceeded 50 mJ/cm² was evaluated as “poor”.

### [LWR Performance]

A resist pattern was formed with the mask size adjusted so as to form a 27 nm line- and -space pattern by irradiation with the optimum exposure dose obtained in the evaluation of the sensitivity. The formed resist pattern was observed from above the pattern using the scanning electron microscope. The variation in line width was measured at 500 points in total, the value of 30 was obtained from the distribution of the measured values, and the value of 30 was defined as LWR (nm). A smaller value of LWR indicates smaller displacement of the line and better performance. A case where the LWR performance was 3.0 nm or less was evaluated as “good”, and a case where the LWR performance exceeded 3.0 nm was evaluated as “poor”.

### [Pattern Collapse Resistance (Minimum Pre-Collapse Dimension)]

Exposure was performed through the 27 nm line- and -space mask pattern while changing the exposure dose by 1 mJ/cm². The line width of a pattern formed with an exposure dose smaller by 1 mJ/cm² than the exposure dose at which line collapse occurred was measured with the scanning electron microscope and was defined as the minimum pre-collapse dimension (nm). The smaller the value is, the higher the resistance to collapse of the pattern is.

TABLE 7

| | Radiation- | | | Minimum pre- |
|---|---|---|---|---|
| | sensitive | Sensitivity | LWR | collapse dimension |
| | composition | (mJ/cm²) | (nm) | (nm) |
| Example 46 | J-46 | 45 | 2.6 | 17 |
| Example 47 | J-47 | 44 | 2.6 | 19 |
| Example 48 | J-48 | 47 | 2.7 | 17 |
| Example 49 | J-49 | 43 | 2.5 | 14 |
| Example 50 | J-50 | 43 | 2.5 | 15 |
| Example 51 | J-51 | 45 | 2.6 | 14 |
| Example 52 | J-52 | 46 | 2.6 | 12 |
| Example 53 | J-53 | 44 | 2.7 | 16 |
| Example 54 | J-54 | 43 | 2.4 | 14 |
| Example 55 | J-55 | 44 | 2.6 | 15 |
| Example 56 | J-56 | 46 | 2.5 | 16 |
| Example 57 | J-57 | 45 | 2.6 | 13 |
| Comparative | CJ-9 | 54 | 4.5 | 22 |
| Example 9 | | | | |
| Comparative | CJ-10 | 53 | 4.2 | 24 |
| Example 10 | | | | |
| Comparative | CJ-11 | 55 | 4.6 | 25 |
| Example 11 | | | | |
| Comparative | CJ-12 | 52 | 4.1 | 23 |
| Example 12 | | | | |
| Comparative | CJ-13 | 54 | 3.9 | 25 |
| Example 13 | | | | |

As is apparent from the results in Table 7, the radiation-sensitive compositions of Examples were good in sensitivity, LWR performance, and pattern collapse resistance when used for EUV exposure, whereas the radiation-sensitive compositions of Comparative Examples were inferior in the characteristics to those of Examples.

[Preparation of Negative Radiation-Sensitive Composition for ArF Exposure, and Formation and Evaluation of Resist Pattern Using this Composition]

### Example 58

100 parts by mass of (A-1) as the polymer [A], 10.0 parts by mass of (B-3) as the radiation-sensitive acid generator [B], 4.0 parts by mass of (C-1) as the acid diffusion controlling agent [C], 4.0 parts by mass (solid content) of (E-4) as the high fluorine-content polymer [E], and 3, 230 parts by mass of a mixed solvent of (D-1)/(D-2)/(D-3) (mass ratio: 2240/960/30) as the solvent [D] were mixed, and the mixture was filtered through a membrane filter having a pore size of 0.2 μm to prepare a radiation-sensitive composition (J-58).

A composition for forming an underlayer antireflective film (“ARC66” manufactured by Brewer Science, Inc.) was applied onto a 12 inch silicon wafer using a spin coater (“CLEAN TRACK ACT12” manufactured by Tokyo Electron Limited), and then heated at 205° C. for 60 seconds to form an underlayer antireflective film having an average thickness of 100 nm. The negative radiation-sensitive composition for ArF exposure (J-58) prepared above was applied onto the underlayer antireflective film using the spin coater, and subjected to PB (prebake) at 100° C. for 60 seconds. Thereafter, cooling was performed at 23° C. for 30 seconds to form a resist film having an average thickness of 90 nm. Next, this resist film was exposed through a mask pattern having a hole of 60 nm and a pitch of 120 nm using an ArF excimer laser immersion exposure apparatus (“TWINSCAN XT-1900i” manufactured by ASML) with NA of 1.35 under an optical condition of Annular (σ=0.8/0.6). After the exposure, PEB (post exposure bake) was performed at 100° C. for 60 seconds. Thereafter, the resist film was developed with an organic solvent using n-butyl acetate as an organic solvent developer, and dried to form a negative resist pattern (60 nm hole, 120 nm pitch).

The resist pattern using the negative radiation-sensitive composition for ArF exposure was evaluated on sensitivity in the same manner as in the evaluation of the resist pattern using the positive radiation-sensitive composition for ArF exposure. In addition, CDU performance and pattern circularity were evaluated in accordance with the following methods.

### [CDU Performance]

Contact holes with a 60 nm hole and a 120 nm pitch were formed by irradiation with the optimum exposure dose determined in the evaluation of sensitivity. The formed resist pattern was observed from above the pattern using the scanning electron microscope. The variation of the contact holes was measured at 500 points in total, and the 3 sigma value was determined from the distribution of the measurement values, and defined as CDU (nm). The smaller the value of the CDU is, the smaller the roughness of the contact holes is, which is better. When the value was less than 3.5 nm, the CDU performance was evaluated to be “good”, and when the value was 3.5 nm or more, the CDU performance was evaluated to be “poor”.

### [Pattern Circularity]

The contact holes with a 60 nm hole and a 120 nm pitch formed by irradiation with the optimum exposure dose determined in the evaluation of sensitivity were observed in plan view using the scanning electron microscope, and the size in the longitudinal direction and the size in the lateral direction were measured. When the ratio of the size in the longitudinal direction to the size in the lateral direction was 0.95 or more and less than 1.05, the pattern circularity was evaluated as “A” (extremely good), when the ratio was 0.90 or more and less than 0.95, or 1.05 or more and less than 1.10, the pattern circularity was evaluated as “B” (good), and when the ratio was less than 0.90, or 1.10 or more, the pattern circularity was evaluated as “C” (poor).

As a result, the radiation-sensitive composition of Example 58 had good sensitivity, CDU performance, and pattern circularity even when a negative resist pattern was formed by ArF exposure.

[Preparation of Negative Radiation-Sensitive Composition for EUV Exposure, and Formation and Evaluation of Resist Pattern Using this Composition]

### Example 59

100 parts by mass of (A-14) as the polymer [A], 30.0 parts by mass of (B-2) as the radiation-sensitive acid generator [B], 20.0 parts by mass of (C-8) as the acid diffusion controlling agent [C], 2.0 parts by mass (solid content) of (E-5) as the high fluorine-content polymer [E], and 6,000 parts by mass of a mixed solvent of (D-1)/(D-2) (mass ratio: 4000/2000) as the solvent [D] were mixed, and the mixture was filtered through a membrane filter having a pore size of 0.2 μm to prepare a radiation-sensitive composition (J-59).

A composition for forming an underlayer antireflective film (“ARC66” manufactured by Brewer Science, Inc.) was applied onto a 12 inch silicon wafer using a spin coater (“CLEAN TRACK ACT12” manufactured by Tokyo Electron Limited), and then heated at 205° C. for 60 seconds to form an underlayer antireflective film having an average thickness of 30 nm. The negative radiation-sensitive composition for EUV exposure (J-59) prepared above was applied onto the underlayer antireflective film using the spin coater, and subjected to PB at 130° C. for 60 seconds. Thereafter, cooling was performed at 23° C. for 30 seconds to form a resist film having an average thickness of 30 nm. Subsequently, this resist film was exposed with an EUV exposure apparatus (“NXE3300” manufactured by ASML Holding N.V.) with an NA of 0.33 under an illumination condition of conventional illumination (s=0.89), and with a mask of imecDEFECT32FFR15. After the exposure, PEB was performed at 120° C. for 60 seconds. Thereafter, the resist film was developed with an organic solvent using n-butyl acetate as an organic solvent developer, and dried to form a negative resist pattern (pattern of contact holes with a 20 nm hole and a 40 nm pitch).

The resist pattern formed using the negative radiation-sensitive composition for EUV exposure was evaluated in the same manner as in the evaluation of the resist pattern formed using the negative radiation-sensitive composition for ArF exposure. As a result, the radiation-sensitive composition of Example 59 had good sensitivity, CDU performance, and pattern circularity even when a negative resist pattern was formed by EUV exposure.

According to the radiation-sensitive composition, the method for forming a pattern, and the onium salt described above, a resist pattern having good sensitivity to exposure light and being superior in LWR performance, DOF performance, pattern rectangularity, EL performance, pattern collapse resistance, CDU performance, and pattern circularity can be formed. Therefore, these can be suitably used for a processing process of a semiconductor device in which micronization is expected to further progress in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive composition comprising:
an onium salt represented by formula (1);
a polymer comprising a structural unit (I) which comprises an acid-dissociable group; and
a solvent: 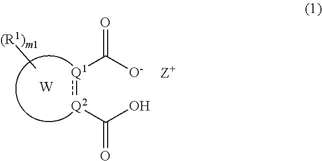
wherein,
Q¹ and Q² are each independently a carbon atom or a nitrogen atom, provided that at least one selected from the group consisting of Q¹ and Q² is a carbon atom,
W is a monocyclic or polycyclic non-aromatic ring structure of 3 to 40 ring members constituted together with Q¹ and Q² in the formula, and
the following formula between Q¹ and Q² in formula (1) represents a single bond or a double bond, [symbol]
R¹ is a monovalent organic group having 1 to 20 carbon atoms, a nitro group, a hydroxy group, an amino group, a thiol group, a cyano group, a carboxy group, or halogen atom, when there are a plurality of R¹'s, the plurality of R¹'s are the same or different from each other,
m₁ is an integer of 0 to 4, and
Z⁺ is a monovalent onium cation.

2. The radiation-sensitive composition according to claim 1, wherein the non-aromatic ring structure is a monocyclic or polycyclic aliphatic hydrocarbon structure having 3 to 20 carbon atoms, a monocyclic or polycyclic aliphatic heterocyclic structure having 3 to 20 carbon atoms, or a combination thereof.

3. The radiation-sensitive composition according to claim 1, wherein the non-aromatic ring structure is at least one non-aromatic ring structure selected from the group consisting of a cyclopentane ring, a cyclohexane ring, a cycloheptane ring, a cyclooctane ring, a norbornane ring, a tricyclodecane ring, a tetracyclododecane ring, and an adamantane ring, a part of carbon atoms constituting the at least one non-aromatic ring structure being optionally replaced with —O—, —CO—, or a combination thereof.

4. The radiation-sensitive composition according to claim 1, wherein Z⁺ is a monovalent sulfonium cation comprising at least one aromatic ring or a monovalent iodonium cation comprising at least one aromatic ring.

5. The radiation-sensitive composition according to claim 1, wherein a content of the onium salt in the radiation-sensitive composition is 0.1 parts by mass or more and 30 parts by mass or less with respect to 100 parts by mass of the polymer.

6. The radiation-sensitive composition according to claim 1, wherein the structural unit (I) is represented by formula (3): 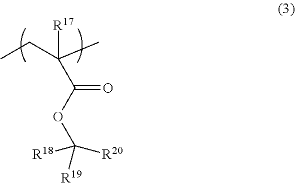
wherein,
R¹⁷ is a hydrogen atom, a fluorine atom, a methyl group, or a trifluoromethyl group,
R¹⁸ is a monovalent hydrocarbon group having 1 to 20 carbon atoms, and
R¹⁹ and R²⁰ are each independently a monovalent chain hydrocarbon group having 1 to 10 carbon atoms or represent a monovalent alicyclic hydrocarbon group having 3 to 20 carbon atoms or R¹⁹ and R²⁰ taken together represent a divalent alicyclic group having 3 to 20 carbon atoms together with the carbon atoms to which R¹⁹ and R²⁰ are bonded.

7. The radiation-sensitive composition according to claim 6, wherein
in formula (3),
R¹⁸, R¹⁹, and R²⁰ are each independently a monovalent hydrocarbon group having 1 to 20 carbon atoms; or
R¹⁸ is a monovalent hydrocarbon group having 1 to 20 carbon atoms, and R¹⁹ and R²⁰ taken together represent a divalent polycyclic aliphatic hydrocarbon group having 5 to 20 carbon atoms together with the carbon atoms to which R¹⁹ and R²⁰ are bonded.

8. The radiation-sensitive composition according to claim 1, wherein a content ratio of the structural unit (I) in the polymer to all structural units constituting the polymer is 10 mol % or more and 90 mol % or less.

9. The radiation-sensitive composition according to claim 1, wherein the polymer further comprises a structural unit (II) comprising at least one selected from the group consisting of a polycyclic lactone structure, a cyclic carbonate structure, and a sultone structure.

10. The radiation-sensitive composition according to claim 9, wherein a content ratio of the structural unit (II) in the polymer to all structural units constituting the polymer is 10 mol % or more and 90 mol % or less.

11. The radiation-sensitive composition according to claim 1, further comprising a radiation-sensitive acid generator that generates an acid having a pka lower than a pKa of an acid generated from the onium salt by irradiation with radiation.

12. A method for forming a pattern, comprising:
directly or indirectly applying the radiation-sensitive composition according to claim 1 to a substrate to form a resist film;
exposing the resist film to light; and
developing the resist film exposed to light with a developer.

13. The method for forming a pattern according to claim 12, wherein the resist film is exposed to light by an ArF excimer laser or extreme ultraviolet rays.

14. An onium salt represented by formula (1): 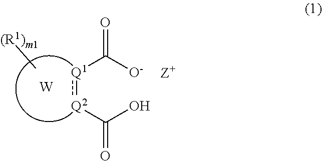
wherein,
Q¹ and Q² are each independently a carbon atom or a nitrogen atom, provided that at least one selected from the group consisting of Q¹ and Q² is a carbon atom,
W is a monocyclic or polycyclic non-aromatic ring structure of 3 to 40 ring members constituted together with Q¹ and Q² in the formula, and
the following formula between Q¹ and Q² in formula (1) represents a single bond or a double bond, [symbol]
R¹ is a monovalent organic group having 1 to 20 carbon atoms, a nitro group, a hydroxy group, an amino group, a thiol group, a cyano group, a carboxy group, or halogen atom, when there are a plurality of R¹'s, the plurality of R¹'s are the same or different from each other,
m₁ is an integer of 0 to 4, and
Z⁺ is a monovalent onium cation.

15. The onium salt according to claim 14, wherein Z⁺ is a monovalent sulfonium cation comprising at least one aromatic ring or a monovalent iodonium cation comprising at least one aromatic ring.
